(19) United States
(12) Patent Application Publication
(10) Pub. No.: US 2023/0413684 A1
(43) Pub. Date: Dec. 21, 2023

(54) VALLEYTRONIC LOGIC DEVICES COMPRISING MONOCHALCOGENIDES

(71) Applicant: Intel Corporation, Santa Clara, CA (US)

(72) Inventors: Punyashloka Debashis, Hillsboro, OR (US); Hai Li, Portland, OR (US); Chia-Ching Lin, Portland, OR (US); Dmitri Evgenievich Nikonov, Beaverton, OR (US); Ian Alexander Young, Olympia, WA (US)

(73) Assignee: Intel Corporation, Santa Clara, CA (US)

(21) Appl. No.: 17/843,976

(22) Filed: Jun. 18, 2022

(51) Int. Cl. H01L 43/10; H01L 27/22; H01L 43/04; H01L 43/06; H01L 43/14

(52) U.S. Cl. CPC H01L 43/10; H01L 27/228; H01L 43/04; H01L 43/065; H01L 43/14

(57) ABSTRACT

Valleytronic devices comprise a channel layer having ferrovalley properties—band-spin splitting and Berry curvature dependence on the polarization of the channel layer. Certain monochalcogenides possess these ferrovalley properties. Valleytronic devices utilize ferrovalley properties to store and/or carry information. Valleytronic devices can comprise a cross geometry comprising a longitudinal portion and a transverse portion. A spin-polarized charge current injected into the longitudinal portion of the device is converted into a voltage output across the transverse portion via the inverse spin-valley Hall effect whereby charge carriers acquire an anomalous velocity in proportion to the Berry curvature and an applied in-plane electric field resulting from an applied input voltage. Due to the Berry curvature dependency on the material polarization, switching the polarity of the input voltage that switches the channel layer polarization also switches the polarity of the differential output voltage.

### BACKGROUND

Numerous materials (even as common as silicon or germanium) have the electronic band structure where the transport of carriers occurs at multiple compact regions of the electron momentum space, called ‘valleys’. Moreover, some materials possess topological properties. An example of such topological properties are quantum states of electrons with a geometrical phase (e.g., Berry phase) of the wave function accumulated as the parameter (e.g., momentum) of the electron is varied along a loop. Berry phase is exhibited by, for example, topological insulator materials such as Bi₂Se₃. The curvature of the Berry phase in the momentum space functions as a gauge field, or in other words, an effective magnetic field inherent in such materials.

Valleytronic devices utilize valley-dependent properties of materials to store and/or carry information. Some ferroelectric monochalcogenides, when sufficiently thin (e.g., in monolayer form), possess certain ferrovalley properties—the splitting of energy bands into electron-spin dependent sub-bands and Berry curvature dependency on the polarization of the monochalcogenide material—utilized by valleytronic devices.

### BRIEF DESCRIPTION OF THE DRAWINGS

FIG. 1 illustrates an example differential magnetoelectric spin-orbit (MESO) logic device.

FIG. 2 illustrates energy bands for an example material possessing ferrovalley properties.

FIG. 3A illustrates a first example valleytronic logic device.

FIGS. 3B and 3C illustrate cross-sectional views of the valleytronic device of FIG. 3 taken along the lines A-A′ and B-B′, respectively.

FIG. 4A illustrates a first example valleytronic logic device.

FIGS. 4B and 4C illustrate cross-sectional views of the valleytronic device of FIG. 4 taken along the lines C-C′ and D-D′, respectively.

FIGS. 5A-5H illustrate cross-sectional views of the example valleytronic device of FIG. 3 taken along the line A-A′ at various stages of fabrication.

FIGS. 6A-6H illustrate cross-sectional views of the example valleytronic device of FIG. 3 taken along the line B-B′ at various stages of fabrication.

FIG. 7 illustrates a flowchart of an example method for fabricating a third example valleytronic device.

FIGS. 8A-8G illustrate cross-sectional views of the example valleytronic device of FIG. 4 taken along the line C-C′ at various stages of fabrication.

FIGS. 9A-9G illustrate cross-sectional views of the example valleytronic device of FIG. 4 taken along the line D-D′ at various stages of fabrication.

FIG. 10 illustrates a flowchart of an example method for fabricating a fourth example valleytronic device.

FIG. 11 is a top view of a wafer and dies that may be included in a microelectronic assembly, in accordance with any of the embodiments disclosed herein.

FIG. 12 is a cross-sectional side view of an integrated circuit device that may be included in a microelectronic assembly, in accordance with any of the embodiments disclosed herein.

FIGS. 13A-13D are perspective views of example planar, FinFET, gate-all-around, and stacked gate-all-around transistors.

FIG. 14 is a cross-sectional side view of an integrated circuit device assembly that may include a microelectronic assembly, in accordance with any of the embodiments disclosed herein.

FIG. 15 is a block diagram of an example electrical device that may include a microelectronic assembly, in accordance with any of the embodiments disclosed herein.

### DETAILED DESCRIPTION

Valleytronic logic refers to a class of integrated circuit devices that utilize valley-dependent characteristics of a material to store and/or carry information. Valleytronic devices can rely on the non-volatile ferroelectric polarization of a material to modify the valley state and thus to store information, which means that the state of a valleytronic device is preserved when power to an integrated circuit component comprising the valleytronic device is switched off. As a result, valleytronic logic is energy efficient and can enable ultralow power sleep states.

Valleytronic logic is another alternative to spintronic logic as the semiconductor industry looks for technologies that go beyond CMOS (complementary metal-oxide-semiconductor) transistor technology as CMOS approaches its scaling limits. Spintronic logic refers to a class of integrated circuit devices that utilize a physical variable of magnetization or spin as a computational variable. Like valleytronic devices, the physical variable used in spintronic logic can be non-volatile, allowing for an energy efficient technology.

Magnetoelectric spin-orbit (MESO) logic refers to a class of spintronic logic that operates using the magnetoelectric effect in conjunction with the spin-orbit coupling effect (e.g., the coupling of an electron's angular momentum with its linear momentum). For example, a MESO device uses magnetoelectric switching to convert an input charge/voltage into a magnetic spin state (e.g., charge-to-spin conversion) and further uses spin-orbit transduction to convert the magnetic spin state back into an output charge/voltage (e.g., spin-to-charge conversion). In this manner, a MESO device can be used to implement a logic device (e.g., a logic switch/gate) with a non-volatile logical state. For example, a logical state represented by an input charge/voltage can be converted into a (non-volatile) magnetic spin state, and the logical state can subsequently be read out by converting the magnetic spin state back into an output charge/voltage.

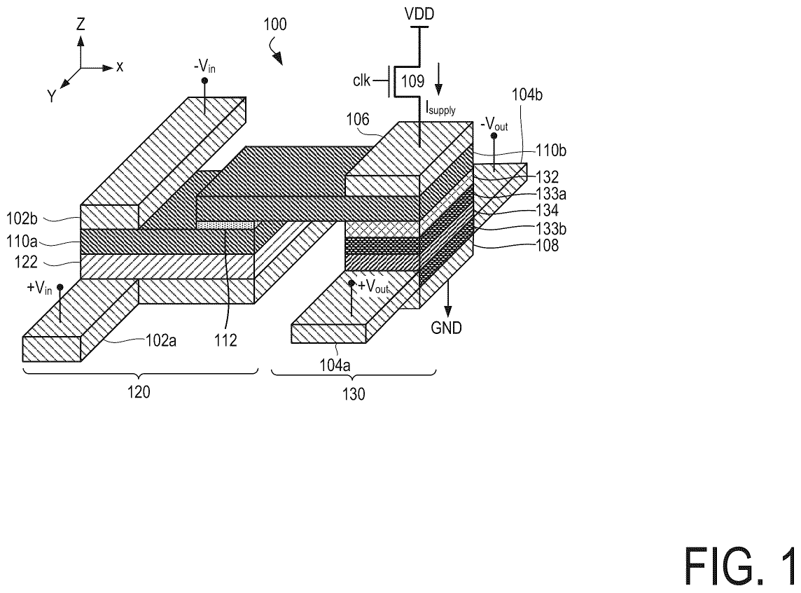

FIG. 1 illustrates an example differential magnetoelectric spin-orbit (MESO) logic device. MESO device 100 includes a ferromagnet 110, a magnetoelectric conversion module 120, and a spin-orbit conversion structure 130. MESO device 100 also includes conductive traces, portions of which serve as electrodes, to provide differential voltage inputs (+/−Vᵢₙ), a power supply (V_{DD}), and ground (GND) 108, and carry differential voltage outputs (+/−Vₒᵤₜ). For example, conductive traces 102a-b provide differential input voltages (+/−Vᵢₙ), conductive traces 104a-b carry differential output voltage signals (+/−Vₒᵤₜ), conductive trace 106 provides power (V_{DD}), and conductive trace 108 provides ground (GND) to the device 100. In other embodiments, the differential input and output voltage terminals (+/−Vᵢₙ and +/−Vₒᵤₜ) may be replaced with a single input voltage terminal (Vᵢₙ) and a single output voltage terminal (Vₒᵤₜ), respectively (e.g., with a conductive trace coupling the input voltage terminal (Vᵢₙ) to the magnetoelectric layer 122, and a conductive trace coupling the spin-orbit coupling layer 134 to the output voltage terminal (Vₒᵤₜ)).

The magnetoelectric module 120 performs charge-to-spin conversion to convert an electric charge current into spin (e.g., inducing a particular direction of magnetization on the ferromagnet 110), and the spin-orbit conversation structure 130 performs spin-to-charge conversion to convert spin (e.g., the direction of magnetization induced on the ferromagnet 110) back into an electric charge current, as described further below.

The ferromagnet 110 is formed by two ferromagnets 110a-b coupled via an inter-magnet insulating layer 112, which collectively function as a single ferromagnet 110. That is, when the magnetization changes on one of the ferromagnets 110a-b, the magnetization orientation on the other ferromagnet changes. Moreover, ferromagnets 110a-b comprise a ferromagnetic material that retains the magnetization setting induced on it, which is to say that it is non-volatile.

The magnetoelectric module 120 includes a structure (e.g., stack of layers) configured to convert an electric charge current into spin (e.g., magnetization). For example, the magnetoelectric module 120 is formed by the positive input voltage (+Vᵢₙ) conductive trace 102a, which in turn is coupled to a magnetoelectric material 122, which in turn is coupled to ferromagnet 110a, which in turn is coupled to the negative input voltage (−Vᵢₙ) interconnect 102b. The magnetoelectric material 122 has both ferroelectric properties (e.g., can be electrically polarized with or without an applied electric field) and magnetic properties (e.g., may exhibit surface spin polarization which can be switched under the application of an external electric field). In this manner, the magnetoelectric module 120 is configured as a capacitor, with ferromagnet 110 and input voltage interconnect 102a serving as electrical plates surrounding the magnetoelectric layer 122.

When voltage is applied via the differential voltage inputs (+/−Vᵢₙ), charge current flows across the magnetoelectric layer 122, which results in ferroelectric polarization in the magnetoelectric layer 122 and forms an electric field in the +/−Z direction depending on the polarity of the input current. For example, when a positive input differential voltage (Vᵢₙ) is applied, the current flow is positive and an electric field forms in the +Z direction, with a positive charge adjacent to positive voltage (+Vᵢₙ) conductive trace 102a and a negative charge (−Vᵢₙ) adjacent to ferromagnet 110a. By contrast, when a negative input differential voltage (Vᵢₙ) is applied, the current flow is negative and an electric field forms in the −Z direction, with a negative charge adjacent positive voltage (+Vᵢₙ) conductive trace 102a and a positive charge adjacent to ferromagnet 110a (−Vᵢₙ).

As charge accumulates in the magnetoelectric module 120, the spin of electrons in the magnetoelectric layer 122 at the interface with ferromagnet 110a becomes aligned to form surface spin polarization, forming a magnetic field. The orientation of magnetization (spin) of the electrons in the surface spin polarization is defined by the orientation of ferroelectric polarization within the magnetoelectric layer 122. As the magnetic field corresponding to the surface spin polarization is formed, it becomes exchange coupled with ferromagnet 110a, causing the magnetization in ferromagnet 110a to align with the magnetic field of the surface spin polarization, which in turn causes the same effect to occur in ferromagnet 110b. In this manner, the orientation of magnetization of the ferromagnet 110 can be switched based on the input current. This setting of the orientation of magnetization of the ferromagnet 110 affects the output of the spin-orbit conversion structure 130, as described below.

The spin-orbit conversion structure 130 is configured to convert spin (e.g., the magnetization) back into an electric charge current. For example, the spin-orbit conversion structure 130 includes a power supply (V_{DD}) conductive trace 106 coupled to ferromagnet 110b, which in turn is coupled to a tunneling barrier 132. Tunneling barrier 132 is coupled to a first spin injection layer 133a, which in turn is coupled to spin-orbit coupling layer 134, which in turn is coupled to a second spin injection layer 133b. Ground conductive trace 108 is coupled to the second spin injection layer 133b. Moreover, in some embodiments, the supply of power to the ferromagnet 110b is controlled via a transistor 109 that has its gate terminal connected to a clock signal or other control signal.

When voltage is applied via the power supply (V_{DD}) conductive trace 106 (e.g., 100 mV), a supply charge current (I_{supply}) flows through ferromagnet 110b. The magnetization of the ferromagnet 110b produces a spin-polarized current in which a substantial majority (e.g., greater than 80%) of electrons associated with the supply charge current (I_{supply}) will exhibit spin (e.g., magnetization) having an orientation corresponding to the magnetization of ferromagnet 110b. The strength of the spin-polarized current (e.g., the proportion of electrons that align with ferromagnet 110b) is proportional to the strength of the magnetization.

After the supply current passes through ferromagnet 110b and becomes a spin-polarized current, the spin-polarized current enters the tunneling barrier 132, which serves as a tunneling barrier to the spin-orbit coupling layer 134. For example, because the ferromagnet 110b has low resistance and the spin-orbit coupling layer 134 has high resistance, if those components are adjacent to each other, spin current can flow from the spin-orbit coupling layer 134 back into the ferromagnet 110b. As a result, the tunneling barrier 132 is placed between the ferromagnet 110b and the spin-orbit coupling layer 134, which serves as a tunneling barrier to prevent spin flow from the spin-orbit coupling layer 134 back into the ferromagnet 110b. In this manner, the spin-polarized current flows from ferromagnet 110b through the tunneling barrier 132 and into the spin-orbit coupling layer 134, with a small amount or no spin flow in the opposite direction. The spin injection layer 133a can further improve the spin polarization of electrons injected into the spin-orbit coupling layer 134.

The spin-orbit coupling layer 134 has a strong or high spin-orbit effect, which is referred to as spin-orbit coupling. As a result, when the spin-polarized current flows through the spin-orbit coupling layer 134, due to the inverse spin-orbit coupling effect, the spin current converts into an output charge current, which produces an output voltage on the differential output conductive traces (+/−Vₒᵤₜ) 104a-b. A spin injection layer 133b is coupled to the spin-orbit coupling layer 134 and the output conductive traces 104a-b.

The transformation of a spin current into a charge current when the spin current flows through a material with high spin-orbit coupling is referred to as the inverse spin-orbit Hall effect (ISOE). When spin-orbit coupling occurs in the bulk of the material as opposed to its interface, this effect is commonly called the inverse spin Hall effect (SHE). By contrast, the standard spin Hall effect is a phenomenon where a charge current transforms into a spin current when the charge current flows through a material with high spin-orbit interaction. The directions of the spins are opposite at opposing lateral boundaries of the material, and the spin polarization is proportional to the current and changes sign when the direction of the current is reversed. Thus, the inverse spin Hall effect is simply the reverse of the spin Hall effect.

In the illustrated example, the spin-orbit conversion structure 130 is configured so that the direction of deflection of the electrons due to the inverse spin Hall effect is either into or away from the differential voltage output conductive traces (+/−Vₒᵤₜ) 104a-b, which serve as an output of the MESO device 100. More particularly, the deflection of electrons produced by the inverse spin Hall effect is along an axis (e.g., the Y-axis) substantially perpendicular to both the supply charge current (I_{supply}) (e.g., the Z-axis) and the spin-polarized current corresponding to the orientation of magnetization (e.g., the X-axis), the two of which are substantially perpendicular to each other. Thus, the differential voltage outputs (+/−Vₒᵤₜ) 104a-b are positioned substantially perpendicular to ferromagnet 110b (and associated orientation of magnetization) and substantially perpendicular to the direction of the supply charge current (I_{supply}). Thus, the spin-orbit coupling layer 134 deflects a majority of electrons into or away from the voltage outputs (+/−Vₒᵤₜ) 104a-b, thereby resulting in an output current that is proportional to the supply charge current (I_{supply}). In this manner, an output voltage is produced on the differential voltage output conductive traces (+/−Vₒᵤₜ) 104a-b, which serves as an output of the MESO device 100. A residual current may also pass through the spin-orbit coupling layer 134 to ground conductive trace 108.

In the illustrated example, the input voltage differential (+/−Vᵢₙ) and the supply charge current (I_{supply}) may be provided during separate operations implemented at different times. More particularly, providing the input voltage differential may be compared to a write operation that sets or adjusts the orientation of magnetization of the ferromagnet 110. Further, providing the supply charge current (I_{supply}) may be compared to a read operation that produces the output voltage differential (+/−Vₒᵤₜ), which is proportional to the magnetization of the ferromagnet 110 previously established during the write operation associated with the input current (Vᵢₙ).

Disclosed herein are valleytronic devices that utilize valley-dependent characteristics of a material to store and/or carry information. This contrasts with electronic and spintronic devices that utilize the charge and spin of electrons, respectively, as the degree of freedom used to store and/or carry information. The valleytronic devices described herein comprise a ferroelectric channel layer having the ferrovalley properties of band spin-splitting—the energy bands being split into two sub-bands, one sub-band corresponding to spin-up electrons and the other sub-band corresponding to spin-down electrons—and Berry curvature dependency on material polarization. As discussed in further detail below, certain monochalcogenides possess these ferrovalley properties.

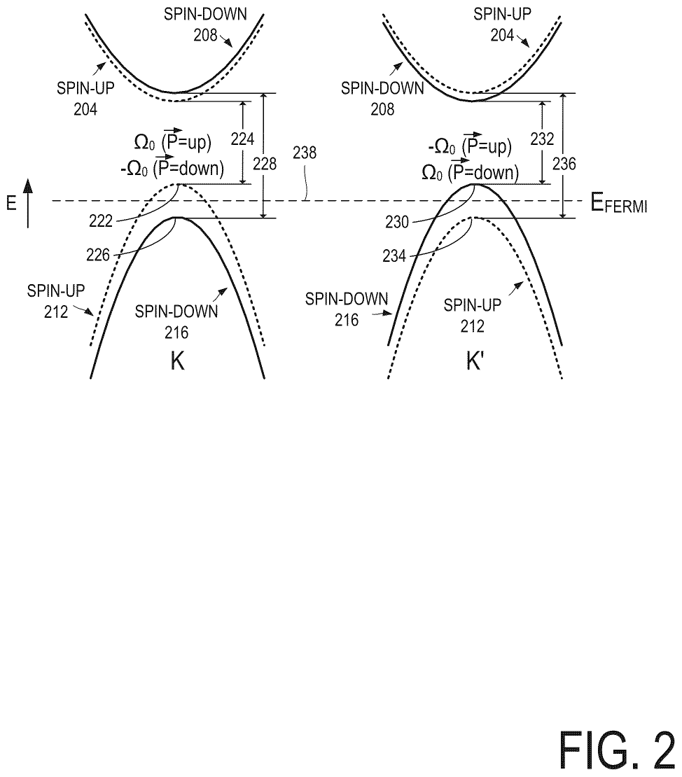

FIG. 2 illustrates energy band extrema for an example ferroelectric material possessing these two ferrovalley properties. FIG. 2 illustrates band spin-splitting and the Berry curvature of the K and K′ valleys of the material under upward- and downward-pointing polarization. The spin-up bands are illustrated as dashed lines and the spin-down bands are illustrated as solid lines. As can be seen, the difference in the energy values of the conduction bands (spin-up bands 204 and the spin-down bands 208) is less than the difference in the energy values of the valence bands (spin-up bands 212 and the spin-down bands 216). The bandgap is the smallest for different spin polarization across the K and K′ valleys. At the K valley maximum, the value 222 of the spin-up valence band 212 is greater than the value 226 of the spin-down valence band 216 (e.g., the spin-up bandgap 224 between the spin-up bands is less the spin-down band gap 228 between the spin-down bands). At the K′ valley maximum, the value 230 of the spin-down valence band 216 is greater than the value 234 of the spin-up valence band 212 (e.g., the spin-down bandgap 232 is less than the spin-up bandgap 236).

Setting the Fermi level 238 of the material between the upper valence band maxima 222 and 230 and the lower valence band maxima 226 and 234, as shown in FIG. 2, allows for valley-selective carrier injection. That is, there will be a valley dependency on the spin polarization of electrons injected from the valence band to the conduction band. A majority of electrons injected into the K valley conduction band from the K valley valence band will be spin-up electrons and the majority of electrons injected into the K′ conduction band from the K′ valence band will be spin-down electrons.

FIG. 2 also illustrates the dependence of the Berry curvature (2o) on the polarization of the ferroelectric material. When the material possesses an upwards polarization, the Berry curvatures of the K and K′ valleys are positive and negative, respectively. When the polarization of the material is reversed and possesses a downwards polarization, the signs of the Berry curvatures of the K and K′ valleys flip and are negative and positive, respectively. Charge carriers in a ferroelectric material possessing ferrovalley characteristics also have an anomalous velocity that is proportional to the cross product of the Berry curvature and an applied electric field (E×Ω₀).

The valleytronic devices herein utilize the band spin-splitting and Berry curvature polarization dependency by injecting a spin-polarized current into the ferroelectric channel layer and controlling the polarization of the channel layer through application of an input voltage to control the polarity of a differential output of the device. As will be discussed in greater detail below, a spin-polarized charge current is injected into the channel layer by passing a charge current through a stack comprising a ferromagnet and a spin injection layer. The ferromagnet causes the charge current to become spin-polarized. If the injected charge current is spin-up polarized, the channel layer conduction band will predominantly comprise spin-up electrons that have jumped from the valence band in which the spin-up valence band maximum has a greater energy than spin-down valence band maximum (e.g., the K valley in FIG. 2). Conversely, if the injected charge current is spin-down polarized, the conduction band of the channel layer will predominantly comprise spin-down electrons that have jumped from the valence band in which the spin-down valence band maximum has a higher energy than spin-up valence band maximum (e.g., the K′ valley in FIG. 2).

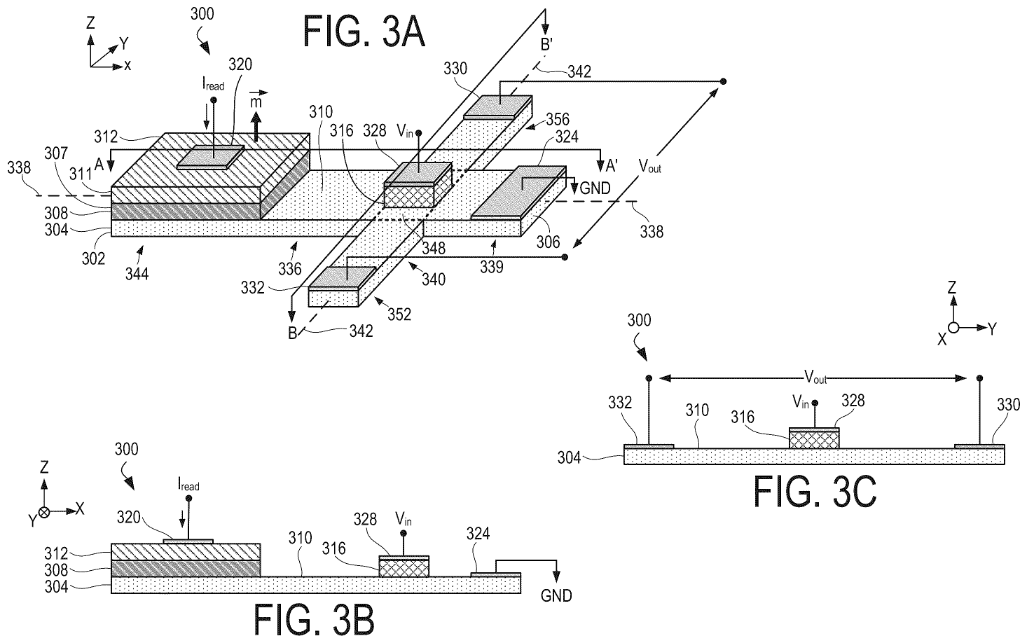

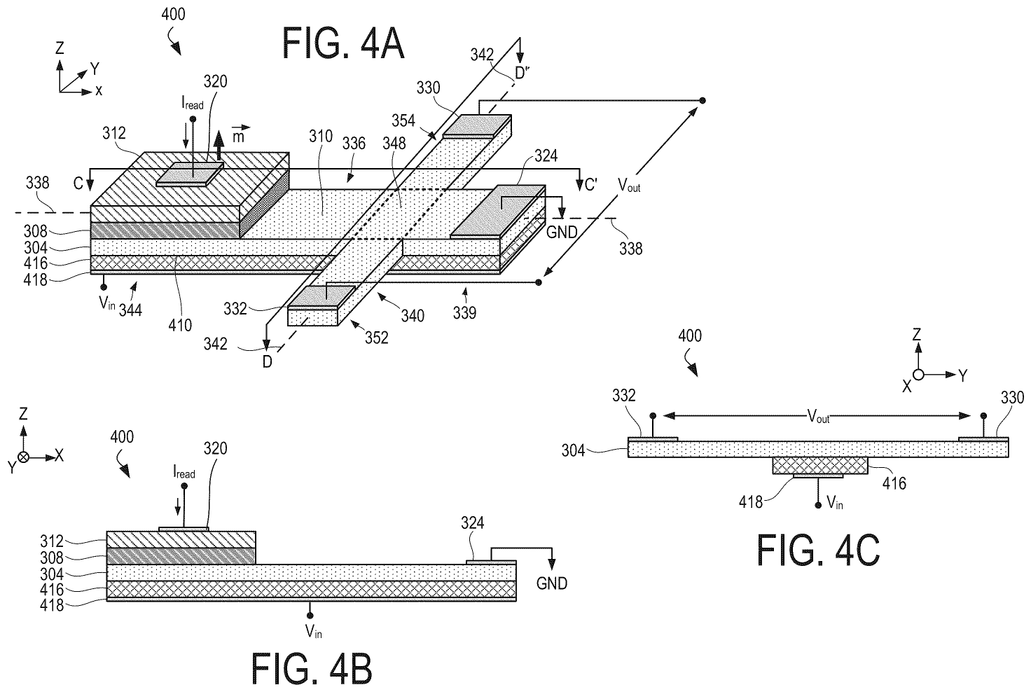

As illustrated in FIGS. 3A and 4A, the valleytronic devices disclosed herein have a cross geometry comprising longitudinal and transverse portions. A spin-polarized read current is injected into the longitudinal portion and a differential output voltage is provided along the transverse portion. The polarity of the differential output voltage depends on the polarity of an input voltage applied to the device. The spin-polarized charge current injected into the longitudinal portion of the device is converted into a differential voltage output across the transverse portion via the inverse spin-valley Hall effect, whereby charge carriers acquire an anomalous velocity proportional to the Berry curvature. The anomalous velocity is along the direction of the transverse portion of the channel layer in the presence of an applied in-plane electric field along the axis of the longitudinal portion of the channel layer resulting from application of the input voltage to the valleytronic device. This inverse spin-valley Halley effect creates an output voltage differential of a first polarity. Due to the dependency of the Berry curvature on the material polarization and that the majority of the injected electrons in the conduction band have the same Berry curvature dependency on the material polarization (due to the valley dependency of the injected charge carriers in the channel layer), switching the polarity of the input voltage applied to the device (which switches the material polarization, and hence, the polarity of the Berry curvature and the anomalous velocity for the charge carriers) switches the polarity of the differential output voltage. Put another way, by switching the ferroelectric polarization of the channel layer through an input voltage, the output charge current (voltage) can be switched, even when the injected spin current remains unchanged.

Thus, the valleytronic devices described herein can convert an input spin current into an output voltage having a polarity depending on the ferroelectric polarization of the channel layer, which can be switched through application of input gate voltage.

The valleytronic devices described herein have at least the following advantages. First, the valleytronic devices have a simpler stack design relative to the MESO device illustrated in FIG. 1. This is due to the channel layer possessing the ferroelectric property needed to set the channel layer polarization and the ferrovalley properties allowing for conversion of a spin current to a charge current that has a material polarization dependency. In contrast, the MESO device of FIG. 1 has separate input module and output module stacks that convert an input current/voltage into a magnetic spin state (input module) and convert the magnetic spin state back into an output charge/voltage (output module). Second, the valleytronic devices described herein can have a larger Vₒᵤₜ magnitude relative to MESO devices due to the long spin lifetimes of the spin current injected into the channel layer and the channel layer material having a resistivity that can be greater than that of materials used in MESO device output modules (which can be heavy metals). Third, since there is no ferromagnetic switching that needs to occur in a valleytronic device for a valleytronic device to switch states, valleytronic device switching speed is not limited to the time it takes to switch the magnetization of a ferromagnet, the time scale of which can be on the order of ones of nanoseconds due to intrinsic material properties, such as Gilbert damping. Fourth, the ferroelectric switching in thin (e.g., monolayer) channel layers may result in valleytronic devices having lower switching voltages than MESO devices due to valleytronic channel layers being thinner than the magnetoelectric and ferromagnet layers used in the input modules of MESO devices, which are typically “bulk” oxides (with “bulk” in this context meaning thicker than a monolayer or thicker than a thinness at which the properties of the material begin to deviate from their bulk properties).

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact with each other and “coupled” may indicate elements cooperate or interact with each other, but they may or may not be in direct physical or electrical contact. Furthermore, the terms “comprising,” “including,” “having,” and the like, as used with respect to embodiments of the present disclosure, are synonymous.

Terms modified by the word “substantially” include arrangements, orientations, spacings, or positions that vary slightly from the meaning of the unmodified term. For example, an axis of a first portion of a valleytronic device that is substantially orthogonal or perpendicular to an axis of a second portion of the valleytronic device includes axes that are within five degrees of being orthogonal to each other, a sidewall of a structure that is substantially perpendicular to a feature includes sidewalls that are within 20 degrees of perpendicular to the feature, and a first surface that is substantially parallel to a second surface can include a first surface that is within several degrees of parallel from the second surface. Values modified by the word “about” include values with +/−10% of the listed values and values listed as being within a range include those within a range from 10% less than the listed lower range limit and 10% greater than the listed higher range limit.

Reference is now made to the drawings, which are not necessarily drawn to scale, wherein similar or same numbers may be used to designate same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well known structures and devices are shown in block diagram form in order to facilitate a description thereof. The intention is to cover all modifications, equivalents, and alternatives within the scope of the claims

As used herein, the phrase “located on” in the context of a first layer or component located on a second layer or component refers to the first layer or component being directly physically attached to the second part or component (with no layers or components between the first and second layers or components) or physically attached to the second layer or component with one or more intervening layers or components. For example, with reference to FIG. 3, the ferromagnet 312 is located on the channel layer 304 (with an intervening spin injection layer 308).

As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y.

As used herein, the term “integrated circuit component” refers to a packaged or unpacked integrated circuit product. A packaged integrated circuit component comprises one or more integrated circuit dies mounted on a package substrate with the integrated circuit dies and package substrate encapsulated in a casing material, such as a metal, plastic, glass, or ceramic. In one example, a packaged integrated circuit component contains one or more processor units mounted on a substrate with an exterior surface of the substrate comprising a solder ball grid array (BGA). In one example of an unpackaged integrated circuit component, a single monolithic integrated circuit die comprises solder bumps attached to contacts on the die. The solder bumps allow the die to be directly attached to a printed circuit board. An integrated circuit component can comprise one or more of any computing system component described or referenced herein or any other computing system component, such as a processor unit (e.g., system-on-a-chip (SoC), processor core, graphics processor unit (GPU), accelerator, chipset processor), I/O controller, memory, or network interface controller.

FIG. 3A illustrates a first example valleytronic logic device. FIGS. 3B and 3C illustrate cross-sectional views of the valleytronic device of FIG. 3A taken along the lines A-A′ and B-B′, respectively. Device 300 comprises a channel layer 304, a spin injection layer 308, a ferromagnet 312, a dielectric layer 316, and conductive traces 320, 324, 328, 330, and 332. The channel layer 304 has a cross shape, comprising a first (or longitudinal) portion 336 extending along an axis 338 and a second (or transverse) portion 340 extending along a second axis 342. The first axis 338 and the second axis 342 are substantially orthogonal to each other. The channel layer 304 comprises a suitable material possessing the ferrovalley properties of band-spin splitting and Berry curvature dependency on channel layer polarization. In some embodiments, the channel layer 304 comprises a ferroelectric monochalcogenide, a material having the chemical composition MX where M can be tin (Sn) or germanium (Ge) and X can be sulfur (S), selenium (Se), and tellurium (Te). Thus, the channel layer 304 can comprise tin sulfide (SnS), tin selenide (SnSe), tin telluride (SnTe), germanium sulfide (GeS), germanium selenide (GeSe), or germanium telluride (GeTe). In some embodiments, the channel layer 304 comprises a compositional alloy having the chemical composition MX₁X₂ where M can be tin or germanium and X₁ and X₂ are two different X elements (e.g., two different elements of sulfur, selenium, and tellurium), such as SnS_{y}Se_{1-y}. In some embodiments, the channel layer 304 comprises a compositional alloy having the chemical composition Ge_{y}Sn_{1-y}X, where X is sulfur, selenium, or tellurium, such as Ge_{y}Sn_{1-y}Te. In some embodiments, the channel layer is a monolayer of a monochalcogenide. In other embodiments, the channel layer comprises multiple layers of a monochalcogenide but is thin enough to still possess the ferrovalley properties of a monochalcogenide monolayer. In some embodiments, the monochalcogenide layer has a thickness in the range of about 1-15 nanometers (nm). In other embodiments, the channel layer comprises a material other than a monochalcogenide that possesses the ferrovalley properties of band spin-splitting and Berry curvature dependency on material polarization.

The spin injection layer 308 is positioned adjacent to a first surface 310 of the channel layer 304 at a first end portion 344 of the first portion 336. The spin injection layer 308, serves the purpose of efficient injection of spin polarization current into the channel layer 304. In some embodiments, the spin injection layer 308 is a dielectric tunneling barrier, such as magnesium oxide (MgO). For example, because the ferromagnet 312 can have low resistance and the channel layer 304 can have high resistance, if those components are adjacent to each other, spin current can flow from the channel layer 304 back into the ferromagnet 312. As a result, the spin injection layer 308 is placed between the ferromagnet 312 and the channel layer 304, which serves as a tunneling barrier to prevent spin flow from the channel layer 304 back into the ferromagnet 312. In this manner, the spin polarized current flows from ferromagnet 312 through the spin injection layer 308 and into the channel layer 304, with a small amount or no spin flow in the opposite direction.

In some valleytronic device embodiments, the spin injection layer 308 is located on the surface 310 of the channel layer 304 with a spin coherence layer positioned between the spin injection layer 308 and the channel layer 304. The spin coherence layer conducts the spin polarized current, and thus possesses the property that its spin-flip length (the length of relaxation of spin polarization) is longer than its thickness. Materials having this property and that can be used as the spin coherence layer include copper and suitable perovskite materials such as those comprising strontium, ruthenium (Ru), titanium, calcium (Ca), manganese (Mn) and/or oxygen, such as SrTiO₃, SrRuO₃, or CaMnO₃.

The spin injection layer 308 can comprise a suitable perovskite material, such as those comprising lanthanum (La), aluminum (Al), tungsten (W), oxygen (O), sodium (Na), tantalum (Ta), strontium (Sr), titanium (Ti), barium (Ba), potassium (K), lithium (Li) and/or niobium (Nb), such as LaAlO₃, WO₃, NaTaO₃, SrTiO₃, BaTiO₃, KTaO₃, LiNbO₃. In some embodiments, the spin injection layer 308 may be formed of any suitable material for tunneling spin current from the ferromagnet 312 to the channel layer 304, such as a tunneling dielectric or tunneling oxide. In some embodiments, for example, the spin injection layer 308 may include magnesium (Mg), aluminum (Al), titanium (Ti), and/or oxygen (O), such as MgO, AlO, and/or TiO, among other examples. Moreover, in some embodiments, the thickness of the spin injection layer 308 is in the range of 0.5-10 nm. In other embodiments, the thickness of the spin injection layer 308 is in the range of 0.5-2.0 nm.

The ferromagnet 312 is positioned adjacent to the spin injection layer 308, with the spin injection layer 308 positioned between the ferromagnet 312 and the channel layer 304. The ferromagnet exhibits perpendicular magnetic anisotropy. That is, its magnetization is aligned perpendicular to the film plane of the ferromagnet 312. With reference to FIG. 3A, the magnetization of the ferromagnet 312 is oriented in the positive z-direction (as indicated by the magnetization vector (m)), perpendicular to the x-y film plane of the ferromagnet 312. In other embodiments, the magnetization of the ferromagnet 312 is oriented in the negative z-direction. The ferromagnet can be formed of any suitable magnetic material, such as a material that includes, for example, cobalt (Co), iron (Fe), nickel (Ni), gadolinium (Gd), and/or their alloys, such as CoFe and/or NiFe, or a magnetic oxide that includes, for example, lanthanum (La), strontium (Sr), manganese (Mn), oxygen (O), calcium (Ca), and/or titanium (TI), such as LaSrMnO₃, Co-doped or Fe-doped perovskite oxide (e.g., CaTiO₃), and/or any other type of oxide magnet, among other examples. As stated earlier, in contrast to the ferromagnet of MESO devices, the magnetization of the ferromagnet 312 is fixed. That is, the magnetization of the ferromagnet 312 does not need to be switched in order to change the polarity of the output voltage (Vₒᵤₜ).

The dielectric layer 316 is positioned adjacent to the surface 310 of the channel layer 304 at a third region 348 of the channel layer 304, the third region 348 being common to the first portion 336 and the second portion 340 of the channel layer 304. The dielectric layer 316 is shown in FIG. 3A as having two edges aligned with the boundary of the third region 348, but the dielectric layer 316 can extend along the first axis 338 in either or both directions beyond the boundaries of the third region 348 and/or extend along the second axis 342 in either or both directions beyond the boundaries of the third region 348. In other embodiments, the dielectric layer 316 can be positioned between the ferromagnet-spin injection layer stack and the third region 348.

The conductive traces 320, 324, 328, 330, and 332 can be an interconnect (such as a line belonging to a metal layer in a metallization stack), a via providing an electrical connection between the device 300 and a line belonging to a metal layer in a metallization stack, or another suitable electrically conductive structure. Conductive trace 320 is positioned adjacent to the ferromagnet 312 and serves to provide a read current (I_{read}) to the device 300. Conductive trace 324 is positioned adjacent to the surface 310 of the channel layer 304 at a second end 339 of the first portion 336 of the channel layer 304. Conductive trace 324 serves to provide ground (GND) to the device 300. Conductive trace 328 is positioned adjacent to the dielectric layer 316, with the dielectric layer 316 positioned between the conductive trace 328 and the channel layer 304. The conductive trace 328 serves to provide an input voltage (Vin) to the device to control the polarization of the channel layer 304. Conductive traces 330 and 332 are positioned adjacent to the surface 310 of the channel layer 304 at a first end 352 and a second end 356, respectively, of the second portion 340 of the channel layer 304. The conductive traces 330 and 332 provide the different output voltage (Vₒᵤₜ) of the device 300. The conductive traces 320, 324, 328, 330, and 332 can be formed of any suitable conductive material (e.g., metal), such as a material that includes, for example, copper (Cu), silver (Ag), aluminum (Al), gold (Au), cobalt (Co), tungsten (W), tantalum (Ta), nickel (Ni), and/or graphene.

The dielectric layer 316 is an electrically insulating layer and can comprise a ferrimagnetic material, such as a material that comprises, for example, ytterbium (Yb), iron (Fe), oxygen (O), nickel (Ni), cobalt (Co), titanium (Ti), magnesium (Mg), aluminum (Al), zinc (Zn), barium (Ba), strontium (Sr), hafnium (Hf), silicon (Si), nitrogen (N), and/or europium (Eu), such as ytterbium iron garnet (Yb₃Fe₂(FeO₄)₃, Yb₃Fe₅O₁₂), MgAl_{0.5}Fe_{1.5}O₄(MAFO), NiAlₓFe₂₋ₓO₄ (NiAFO), a ferromagnetic semiconductor such as EuO, a spinel ferrite such as Fe₃O₄, CoFe₂O₄, Fe₂O₃, Co₂O₃, Co₂FeO₄, Ni₂FeO₄, a hexagonal ferrite having the general chemical formula AₓMe_{y}Fe_{z}Oᵢ (where A can be Ba or Sr and Me can be Co²⁺, Ni²⁺ or Zn²⁺), such as BaFe₁₂O₁₉, or an oxide or nitride insulator such as MgO, Al₂O₃, TiO₂, SiO₂, Si₃N₄, HfO₂. In some embodiments, the dielectric layer 316 can be a suitable nitride or oxide, such as silicon dioxide (SiO₂), carbon-doped silicon dioxide (C-doped SiO₂, also known as CDO or organosilicate glass, which is a material that comprises silicon, oxygen, and carbon), fluorine-doped silicon dioxide (F-doped SiO₂, also known as fluorosilicate glass, which is a material that comprises fluorine, silicon, and oxygen), hydrogen-doped silicon dioxide (H-doped SiO₂, which is a material that comprises silicon, oxygen, and hydrogen), or silicon nitride (Si₃N₄, which is a material that comprises silicon and nitrogen). In some embodiments, the thickness of the dielectric layer 316 is in the range of 1-20 nanometers (nm).

In some embodiments, the conductive traces 320, 324, 330, and 332 are located closer to the portion of the channel layer 304 that is common to the first and second portions 336 and 340 of the channel layer 304 than illustrated in FIG. 3A. That is, the conductive traces 320, 324, 330, and 332 are not located at end portions of the first and second portions 336 and 340 of the channel layer in some embodiments.

The valleytronic device 300 operates by injection of a read charge current (I_{read}) into the ferromagnet 312. The ferromagnet 312 spin-polarizes the read current and the spin-polarized current is injected into the channel layer 304. The spin injection layer 308 aids in the injection of the spin-polarized current in the channel layer 304. Due to the band spin-splitting in the channel layer 304, the injection of carriers into the conduction band of the channel layer 304 occurs predominantly at the valley at which the valence band maximum having the higher energy (spin-down valence band or spin-up valence band) matches the spin polarization of the injected spin-polarized current. In response to an applied in-plane electric field along the axis 338 of the longitudinal portion 336 (resulting from application of the input voltage (Vᵢₙ)), the injected charge carriers drift toward either end (352, 356) of the transverse portion 340 of the device 300, due to the inverse-spin valley Hall effect. Thus, the polarity of the output voltage (Vₒᵤₜ) of the device 300 depends on the direction of the in-plane electric field (which depends on the polarity of the input voltage (Vᵢₙ)), and the spin polarity of the injected spin current.

In some embodiments, the distance 344 from the edge of the spin injection layer 308 to the center of the cross structure (e.g., the center of the region of the channel layer 304 common to the longitudinal and transverse portions 344 and 340, respectively, of the channel layer 304 (the center of the region 348)) should be comparable or less than the spin diffusion length in the channel layer 304 material. In some embodiments, the distance 344 is less than about 170 nm.

The valleytronic device 300 can be used as a logic device (e.g., a logic switch/gate) with a non-voltage logical state. For example, a logical state represented by the input voltage can be converted into a (non-volatile) channel layer polarization state, and the logical state can subsequently be read out by injecting a read current (input current) into the device 300.

Providing the input voltage may be compared to a write operation that sets the polarization of the ferromagnet 312. Further, providing the read current (I_{read}) may be compared to a read operation that produces the output voltage differential (+/−Vₒᵤₜ) that depends on the polarization of the channel layer 304 previously established during the write operation associated with the input voltage (Vᵢₙ).

FIG. 4A illustrates a second example valleytronic device. FIGS. 4B and 4C illustrate cross-sectional views of the valleytronic device of FIG. 4A taken along the lines C-C′ and D-D′, respectively. Device 400 is similar to device 300 but with a conductive trace 418 for providing the input voltage (Vin) and an associated dielectric layer 416 located on a bottom surface 410 of the channel layer 304 that is opposite the top surface 310 of the channel layer 304 upon which conductive traces 320, 324, 330, and 332 are located. The dielectric layer 416 is shown as extending the length of the first portion 336 of the channel layer 304 but can alternatively extend along only a portion of the channel layer 304. For example, in some embodiments, the dielectric layer 416 can be positioned adjacent to the surface 410 of the channel layer 304 at the third region 348 of the channel layer 304. In other embodiments, the dielectric layer 416 can be positioned at a location on the surface 410 between the ferromagnet-spin injection layer stack and the third region 348.

Although FIGS. 3A-3C and 4A-4C show layers with edges aligned with edges of another layer (e.g., end edge 302 of the channel layer 304 is aligned with end edge 307 of the spin injection layer and end edge 311 of the ferromagnet 312), in some embodiments, edges shown as being aligned in FIGS. 3A-3C and 4A-4C may not be aligned. For example, an edge of the ferromagnet 312 may extend past an edge of the spin injection layer 308. That is, an edge of the ferromagnet 312 may overlap an underlying edge of the spin injection layer 308. Similarly, an edge of the spin injection layer 308 may extend past an edge of the ferromagnet 312. Further, an edge of the channel layer 304 can extend past an edge of spin injection layer 308 and/or an edge of the spin injection layer 308 can extend past an edge of the channel layer 304. Moreover, an edge of conductive traces 324, 330, or 332 can extend past an edge of the channel layer 304 and/or an edge of the channel layer 304 can extend past an edge of conductive traces 324, 330, or 332.

The operation of the device 400 is similar to that of device 300, but with the input voltage of device 400 applied to the conductive trace 418 located on the bottom side of the channel layer.

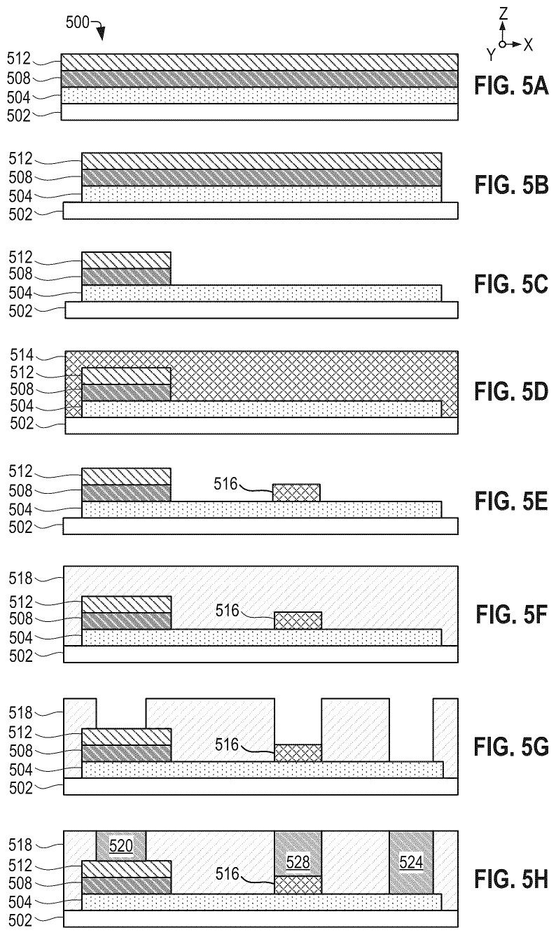

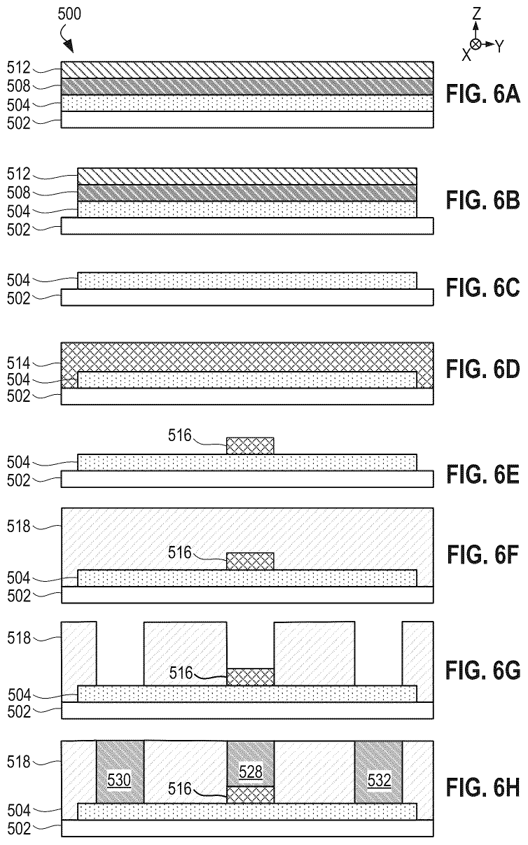

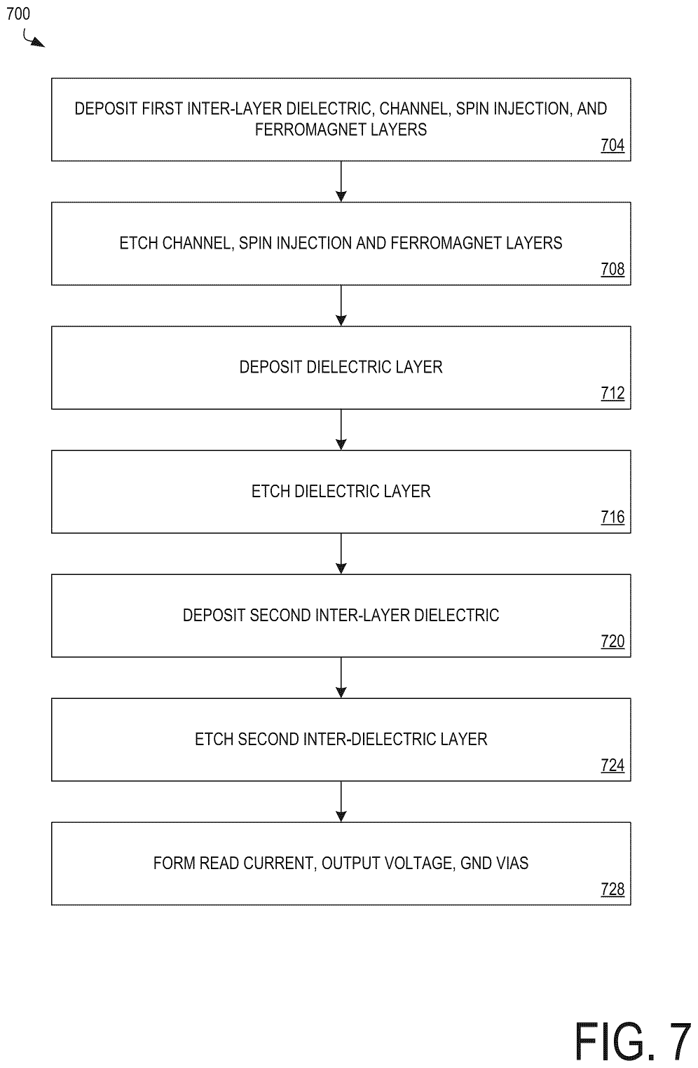

FIGS. 5A-5H and 6A-6H illustrate cross-sectional views of a third example valleytronic device at various stages of fabrication. The valleytronic device 500 has a similar structure to valleytronic device 300, with a longitudinal portion upon which read current, input voltage, and ground terminals are located and a transverse portion upon which output voltage terminals are located. FIGS. 5A-5H illustrate cross-sectional views of the device 500 along the longitudinal axis of the device 500 (e.g., along the line A-A′ of device 300) and FIGS. 6A-6H illustrate cross-section views of the device 500 along the transverse axis of the device 500 (e.g., along the line B-B′ of device 300). FIG. 7 illustrates a flowchart of an example method for fabricating the valleytronic device 500.

Any of the valleytronic fabrication methods described herein, including method 700, may be performed using any suitable microelectronic fabrication techniques. For example, film deposition—such as depositing layers, filling portions of layers (e.g., filling removed portions of layers), and filling via openings—may be performed using any suitable deposition techniques, including, for example, chemical vapor deposition (CVD), metalorganic chemical vapor deposition (MOCVD), molecular beam epitaxy (MBE), atomic layer deposition (ALD), sputtering and/or physical vapor deposition (PVD). Moreover, patterning and removal—such as interconnect patterning, forming via openings, and shaping—may be performed using any suitable techniques, such as lithography-based patterning/masking and/or etching (e.g., dry etch or wet etch).

The method begins at 704, where a first inter-layer dielectric (ILD) layer 502, channel layer 504, spin injection layer 508, and a ferromagnet layer 512 are deposited on or above a substrate (not shown), as shown in FIGS. 5A and 6A. The layers 502, 504, 508, 512 may be deposited from bottom to top in the order shown in FIGS. 5B and 6B. In this manner, the channel layer 504 is positioned adjacent to and between the ILD 502 and spin injection layer 508, and the spin injection layer 508 is positioned adjacent to the ferromagnet layer 512 and in between the channel layer 504 and the ferromagnet layer 512.

At 708, the channel layer 504, the spin injection layer 508, and the ferromagnet layer 512 are shaped by etching away portions of these layers, as shown by FIGS. 5B-5C and 6B-6C. For example, in FIGS. 5B and 6B, the channel layer 504, the spin injection layer 508, and the ferromagnet layer 512 are etched on both sides (left and right sides) to define the extent of the longitudinal and traverse portions of the device 500. In FIGS. 5C and 6C, the spin injection layer 508, and the ferromagnet layer 512 are further etched on one side (e.g., right side), with the etch stopping on the channel layer 504 to define the extent of the ferromagnet-spin injection layer stack.

At 712, a dielectric layer 514 is deposited, as shown in FIGS. 5D and 6D. At 716, the dielectric layer 514 is etched to form a dielectric layer 516 upon which the input voltage conductive trace will be fabricated, as shown in FIGS. 5E and 6E.

At 720, a second ILD layer 518 is deposited, which is then polished, as shown in FIGS. 5F and 6F. At 724, the second ILD layer 518 is etched, as shown in FIGS. 5G and 6G to create openings (via openings) for the read current (I_{read}), input voltage (Vᵢₙ), ground, and the output voltage (+/−Vₒᵤₜ) conductive traces. In the embodiment illustrated in FIGS. 5A-5H and 6A-6H, the conductive traces are vias. At 728, the read current (I_{read}), input voltage (Vᵢₙ), ground, and output voltage (+/−Vₒᵤₜ) via openings are filled and polished, as shown in FIGS. 5H and 6H. In particular, a via 520 that provides the read current to the ferromagnet layer 512 is formed, a via 524 that provides ground to the channel layer 504 is formed; a via 528 that provides the input voltage to the dielectric layer 516 is formed; and vias 530 and 532 that provide the differential output voltage of the device 400 are formed by filling the various via openings.

At this point, the method 700 may be complete. In some embodiments, however, the method 700 may restart and/or certain elements of the method 700 may be repeated. For example, in some embodiments, the method 700 may restart at 704 to fabricate another valleytronic device with the same or different design on top of valleytronic device 600.

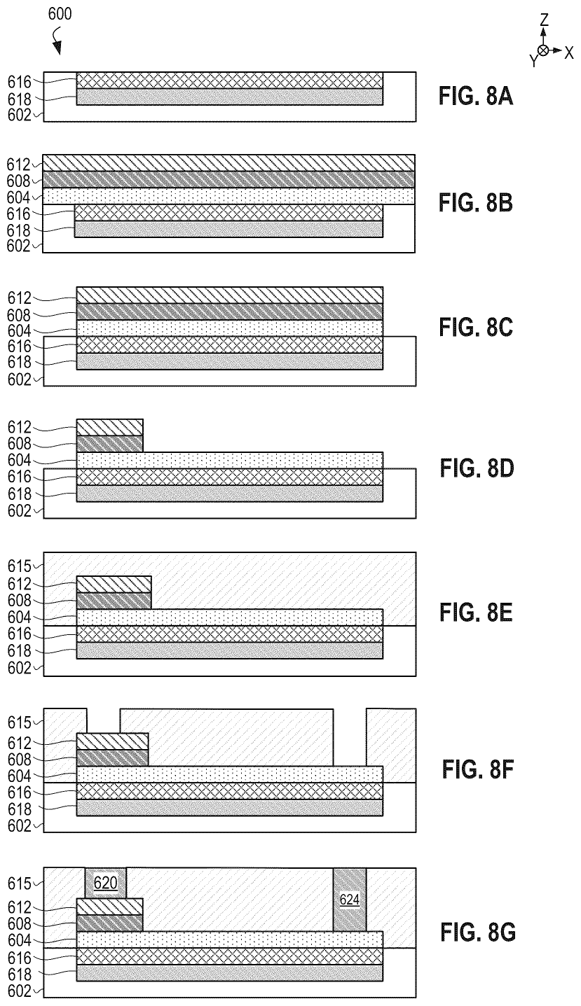

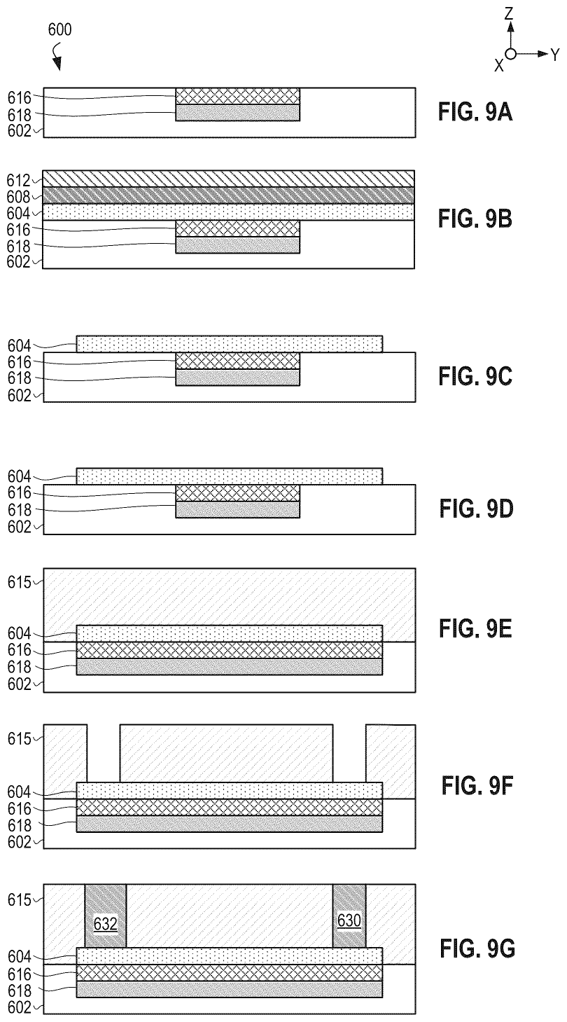

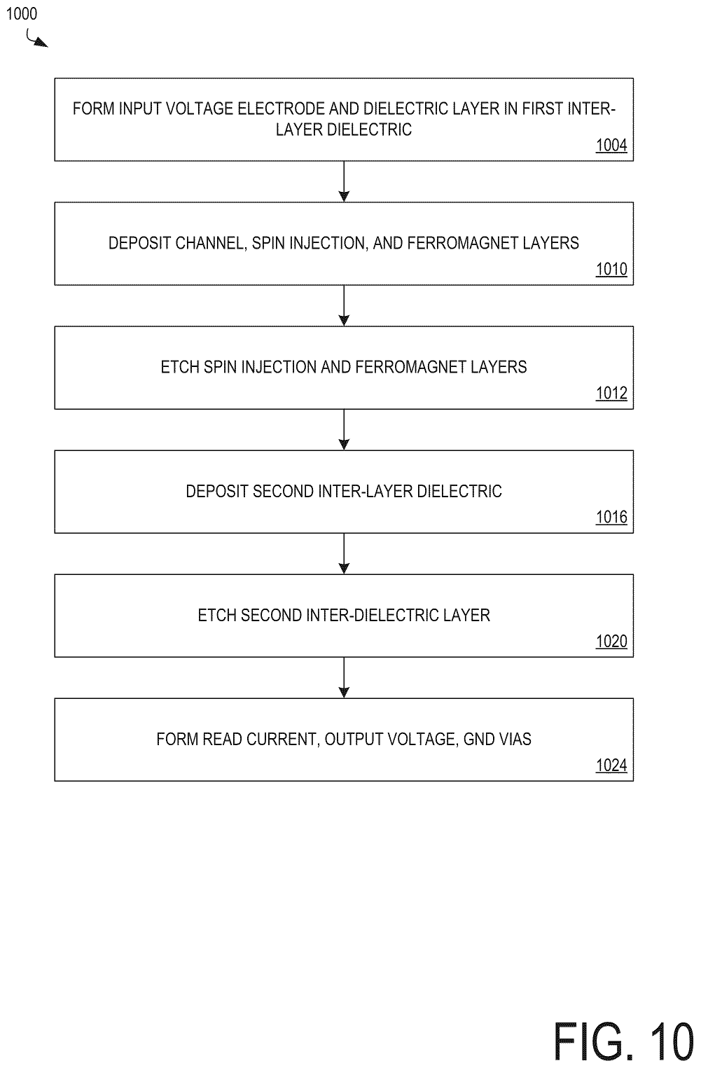

FIGS. 8A-8G and 9A-9G illustrate cross-sectional views of a fourth example valleytronic device at various stages of fabrication. The valleytronic device 600 has a similar structure to valleytronic device 400, with a longitudinal portion on which read current, input voltage, and ground terminals are located (with the input voltage terminal located on an opposite of the channel layer as the read current and ground terminals) and a transverse portion upon which the output voltage terminals are located. FIGS. 8A-8G illustrate cross-sectional views of the device 600 along the longitudinal axis of the device 600 (e.g., along the line C-C′ of device 400) and FIGS. 9A-9G illustrate cross-section views of the device along the transverse axis of the device 600 (e.g., along the line D-D′ of device 400). FIG. 10 illustrates a flowchart of an example method for fabricating the valleytronic device 600. It will be appreciated that methods 700 and 1000 are only two example methodologies for fabricating valleytronic devices as described herein.

The method begins at 1004, where the input voltage (+Vᵢₙ) conductive trace 618 and the dielectric layer 616 associated with the input voltage trace 618 are formed in a first ILD layer 602. For example, after deposition of an ILD layer 602, the ILD layer 602 can be etched to create a recess in which the conductive trace 618 and dielectric layer 616 are to be formed. The conductive trace 618 and the dielectric layer 616 can then be selectively deposited (by, for example, a photolithography process) in the recess, as shown in FIGS. 8A and 9A.

At 1008, a channel layer 604, spin injection layer 608, and a ferromagnet layer 612 are deposited on the ILD layer 602 and the dielectric layer 616, as shown in FIGS. 8B and 9B. The layers 604, 608, and 612 may be deposited from bottom to top in the order shown in FIGS. 8B and 9B. In this manner, the channel layer 604 is positioned adjacent to and between the ILD 602/dielectric layer 616 and spin injection layer 608, and the spin injection layer 608 is positioned adjacent to the ferromagnet layer 612 and in the between the channel layer 604 and the ferromagnet layer 612.

At 1012, the channel layer 604, the spin injection layer 608, and the ferromagnet layer 612 are shaped by etching away portions of these layers, as shown by FIGS. 8C-8D and 9C-9D. For example, in FIGS. 8C and 9C, the channel layer 604, the spin injection layer 608, and the ferromagnet layer 612 are etched on both sides (left and right sides) to define the extent of the longitudinal and traverse portions of the device 600. In FIG. 8D, the spin injection layer 608 and the ferromagnet layer 612 are further etched on one side (e.g., right side), with the etch stopping on the channel layer 604 to define the extent of the spin injection layer-ferromagnet layer stack.

At 1016, a second ILD layer 615 is deposited, which is then polished, as shown in FIGS. 8E and 9E. At 1020, the second ILD layer 615 is etched, as shown in FIGS. 8F and 9F to create openings (via openings) for the read current (I_{read}), ground, and the output voltage (+/−Vₒᵤₜ) conductive traces. In the embodiment illustrated in FIGS. 8A-8G and 9A-9G, the conductive traces are vias. At 1024, the read current (I_{read}), ground, and output voltage (+/−Vₒᵤₜ) via openings are filled and polished, as shown in FIGS. 8G and 9G. In particular, a via 620 that provides the read current to the ferromagnet layer 612 is formed, a via 624 that provides ground to the channel layer 604 is formed; and vias 630 and 632 that provide the differential output voltage of the device 600 are formed by filling the various via openings.

At this point, the method 1000 may be complete. In some embodiments, however, the method 1000 may restart and/or certain elements of the method 1000 may be repeated. For example, in some embodiments, the method 1000 may restart at 1004 to fabricate another valleytronic device with the same or different design on top of valleytronic device 800.

The dielectric layers 502, 514, 516, 518, 602, 615, and 616 can comprise any material that comprises any other dielectric or inter-layer dielectric layers described or referenced herein (e.g., 316, 416). The channel layers 504 and 604 can comprise any material that comprises any other channel layer described or referenced herein (e.g., 304). The spin injection layers 508 and 608 can comprise any of the materials that comprise any spin injection layer described or referenced herein (e.g., 308). The ferromagnet layers 512 and 612 can comprise any of the materials that comprise any ferromagnet described or referenced herein (e.g., 312). The conductive traces 520, 524, 528, 530, 532, 618, 620, 624, 630, and 632 can comprise any material that comprises any other conductive trace (e.g., interconnect, metal line, or via, such as 320, 324, 328, 330, 332, and 418).

The valleytronic devices described herein can be used in any processor unit or integrated circuit component described or referenced herein. An integrated circuit component comprising valleytronic devices can be attached to a printed circuit board (motherboard, mainboard). In some embodiments, one or more additional integrated circuit components or other components (e.g., battery, antenna) can be attached to the printed circuit board. In some embodiments, the printed circuit board and the integrated circuit component can be located in a computing device that comprises a housing that encloses the printed circuit board and the integrated circuit component.

The valleytronic devices can be fabricated as part of an integrated circuit structure. The integrated circuit structure can comprise a die substrate, such as a die substrate comprising silicon, and one or more interconnect layers. The integrated circuit structure can comprise other types of devices, such as electronic transistors (transistors such as CMOS transistors that operate through control of the flow of electric current). A valleytronic device can connect to other valleytronic devices or other types of devices in the integrated circuit structure by one or more interconnect layers (and vias) or by being directly connected to another valleytronic device or another device type.

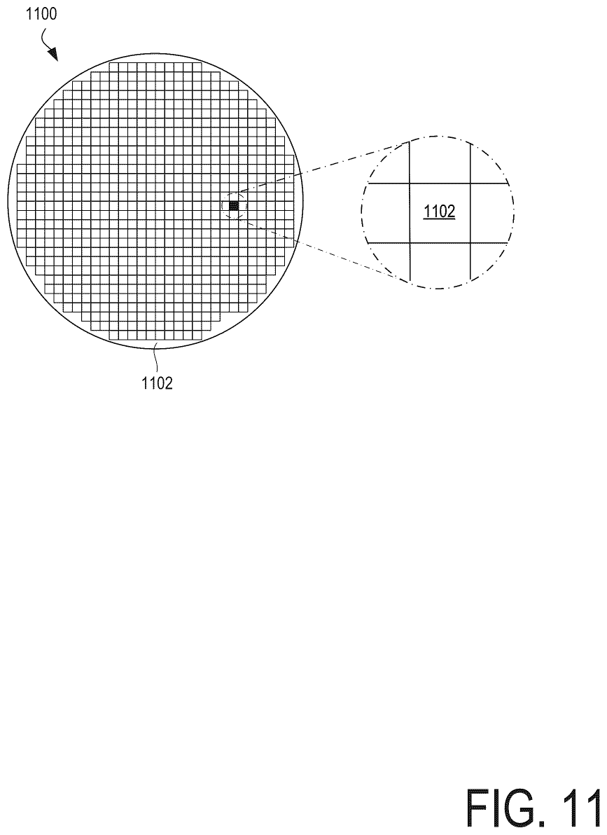

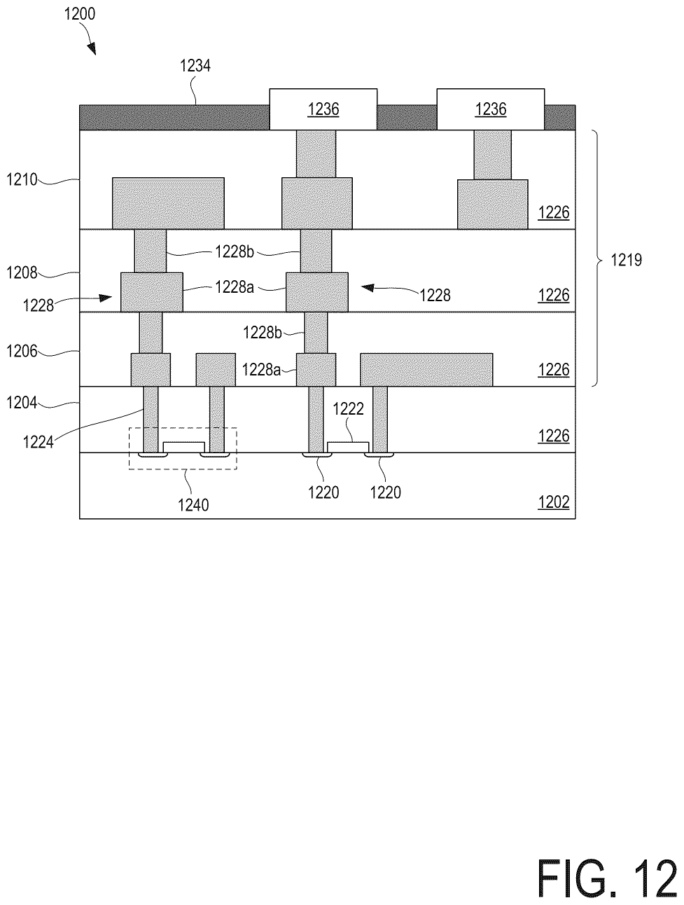

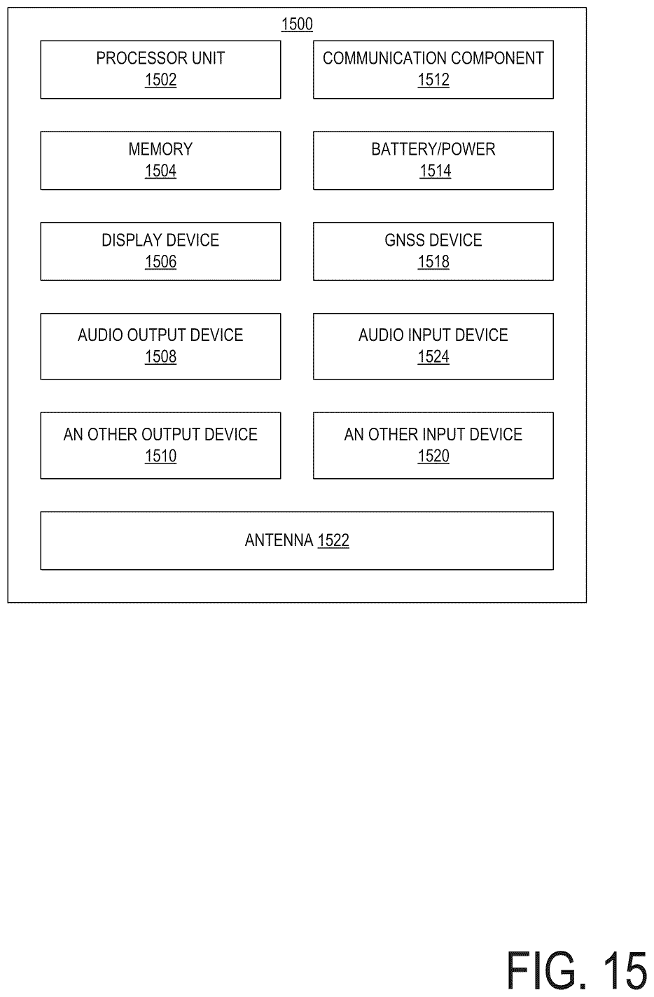

FIG. 11 is a top view of a wafer 1100 and dies 1102 that may include any of the valleytronic devices disclosed herein (e.g., 300, 400, 500, 600). The wafer 1100 may be composed of semiconductor material and may include one or more dies 1102 having integrated circuit structures formed on a surface of the wafer 1100. The individual dies 1102 may be a repeating unit of an integrated circuit product that includes any suitable integrated circuit. After the fabrication of the semiconductor product is complete, the wafer 1100 may undergo a singulation process in which the dies 1102 are separated from one another to provide discrete “chips” of the integrated circuit product. The die 1102 may be any integrated circuit die disclosed herein. The die 1102 may include one or more transistors (e.g., some of the transistors 1240 of FIG. 12, discussed below), supporting circuitry to route electrical signals to the transistors, passive components (e.g., signal traces, resistors, capacitors, or inductors), and/or any other integrated circuit components. In some embodiments, the wafer 1100 or the die 1102 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1102. For example, a memory array formed by multiple memory devices may be formed on a same die 1102 as a processor unit (e.g., the processor unit 1502 of FIG. 15) or other logic that is configured to store information in the memory devices or execute instructions stored in the memory array. Various ones of the microelectronic assemblies disclosed herein may be manufactured using a die-to-wafer assembly technique in which some dies are attached to a wafer 1100 that include other dies, and the wafer 1100 is subsequently singulated.

FIG. 12 is a cross-sectional side view of an integrated circuit device 1200 that may be included in any of the microelectronic assemblies disclosed herein (e.g., in any of the dies disclosed herein). One or more of the integrated circuit devices 1200 may be included in one or more dies 1102 (FIG. 11). The integrated circuit device 1200 may be formed on a die substrate 1202 (e.g., the wafer 1100 of FIG. 11) and may be included in a die (e.g., the die 1102 of FIG. 11). The die substrate 1202 may be a semiconductor substrate composed of semiconductor material systems including, for example, n-type or p-type materials systems (or a combination of both). The die substrate 1202 may include, for example, a crystalline substrate formed using a bulk silicon or a silicon-on-insulator (SOI) substructure. In some embodiments, the die substrate 1202 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1202. Although a few examples of materials from which the die substrate 1202 may be formed are described here, any material that may serve as a foundation for an integrated circuit device 1200 may be used. The die substrate 1202 may be part of a singulated die (e.g., the dies 1102 of FIG. 11) or a wafer (e.g., the wafer 1100 of FIG. 11).

The integrated circuit device 1200 may include one or more device layers 1204 disposed on the die substrate 1202. The device layer 1204 may include features of one or more transistors 1240 (e.g., metal oxide semiconductor field-effect transistors (MOSFETs)) formed on the die substrate 1202. The transistors 1240 may include, for example, one or more source and/or drain (S/D) regions 1220, a gate 1222 to control current flow between the S/D regions 1220, and one or more S/D contacts 1224 to route electrical signals to/from the S/D regions 1220. The transistors 1240 may include additional features not depicted for the sake of clarity, such as device isolation regions, gate contacts, and the like. The transistors 1240 are not limited to the type and configuration depicted in FIG. 12 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

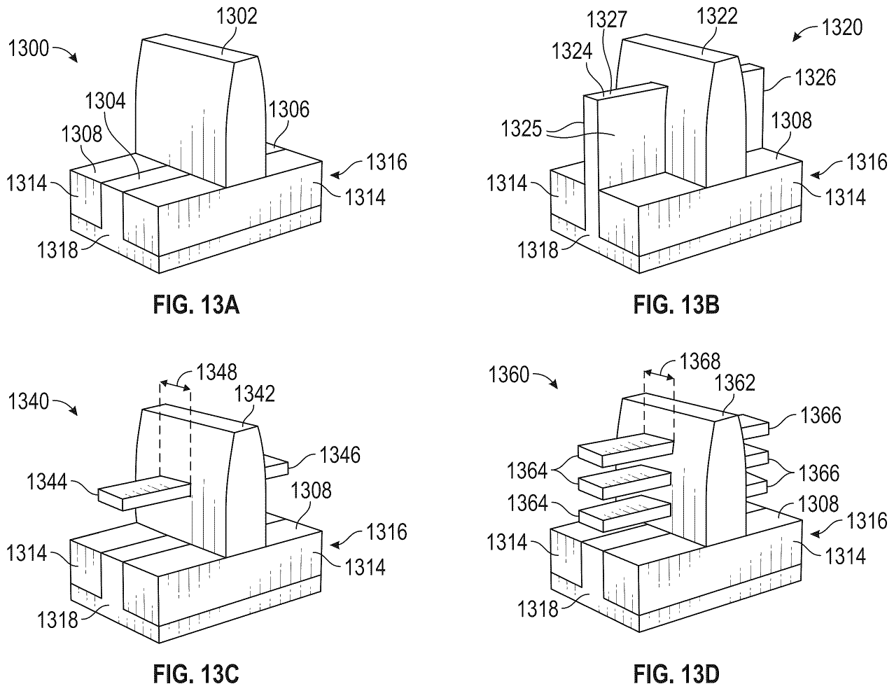

FIGS. 13A-13D are simplified perspective views of example planar, FinFET, gate-all-around, and stacked gate-all-around transistors that can be located on the same integrated circuit die as a valleytronic device. The transistors illustrated in FIGS. 13A-13D are formed on a substrate 1316 having a surface 1308. Isolation regions 1314 separate the source and drain regions of the transistors from other transistors and from a bulk region 1318 of the substrate 1316.

FIG. 13A is a perspective view of an example planar transistor 1300 comprising a gate 1302 that controls current flow between a source region 1304 and a drain region 1306. The transistor 1300 is planar in that the source region 1304 and the drain region 1306 are planar with respect to the substrate surface 1308.

FIG. 13B is a perspective view of an example FinFET transistor 1320 comprising a gate 1322 that controls current flow between a source region 1324 and a drain region 1326. The transistor 1320 is non-planar in that the source region 1324 and the drain region 1326 comprise “fins” that extend upwards from the substrate surface 1328. As the gate 1322 encompasses three sides of the semiconductor fin that extends from the source region 1324 to the drain region 1326, the transistor 1320 can be considered a tri-gate transistor. FIG. 13B illustrates one S/D fin extending through the gate 1322, but multiple S/D fins can extend through the gate of a FinFET transistor. Although the fin 1324 is shown as having sidewalls 1325 that extended substantially perpendicular from the surface 1308 and a top surface 1327 that is substantially orthogonal to the sidewalls, in some embodiments, the fin 1324 can have a tapered cross-sectional profile in which the fin narrows as it extends away from the surface 1308. In some embodiments, a tapered fin can have a rounded end or an end that otherwise may does not have a top surface (e.g., 1327) distinct from its sidewalls.

FIG. 13C is a perspective view of a gate-all-around (GAA) transistor 1340 comprising a gate 1342 that controls current flow between a source region 1344 and a drain region 1346. The transistor 1340 is non-planar in that the source region 1344 and the drain region 1346 are elevated from the substrate surface 1328.

FIG. 13D is a perspective view of a GAA transistor 1360 comprising a gate 1362 that controls current flow between multiple elevated source regions 1364 and multiple elevated drain regions 1366. The transistor 1360 is a stacked GAA transistor as the gate controls the flow of current between multiple elevated S/D regions stacked on top of each other. The transistors 1340 and 1360 are considered gate-all-around transistors as the gates encompass all sides of the semiconductor portions that extends from the source regions to the drain regions. The transistors 1340 and 1360 can alternatively be referred to as nanowire, nanosheet, or nanoribbon transistors depending on the width (e.g., widths 1348 and 1368 of transistors 1340 and 1360, respectively) of the semiconductor portions extending through the gate.

Returning to FIG. 12, a transistor 1240 may include a gate 1222 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1240 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1240 along the source-channel-drain direction, the gate electrode may consist of a U-shaped structure that includes a bottom portion substantially parallel to the surface of the die substrate 1202 and two sidewall portions that are substantially perpendicular to the top surface of the die substrate 1202. In other embodiments, at least one of the metal layers that form the gate electrode may simply be a planar layer that is substantially parallel to the top surface of the die substrate 1202 and does not include sidewall portions substantially perpendicular to the top surface of the die substrate 1202. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1220 may be formed within the die substrate 1202 adjacent to the gate 1222 of individual transistors 1240. The S/D regions 1220 may be formed using an implantation/diffusion process or an etching/deposition process, for example. In the former process, dopants such as boron, aluminum, antimony, phosphorous, or arsenic may be ion-implanted into the die substrate 1202 to form the S/D regions 1220. An annealing process that activates the dopants and causes them to diffuse farther into the die substrate 1202 may follow the ion-implantation process. In the latter process, the die substrate 1202 may first be etched to form recesses at the locations of the S/D regions 1220. An epitaxial deposition process may then be carried out to fill the recesses with material that is used to fabricate the S/D regions 1220. In some implementations, the S/D regions 1220 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1220 may be formed using one or more alternate semiconductor materials such as germanium or a group III-V material or alloy. In further embodiments, one or more layers of metal and/or metal alloys may be used to form the S/D regions 1220.

Electrical signals, such as power and/or input/output (I/O) signals, may be routed to and/or from the devices (e.g., transistors 1240) of the device layer 1204 through one or more interconnect layers disposed on the device layer 1204 (illustrated in FIG. 12 as interconnect layers 1206-1210). For example, electrically conductive features of the device layer 1204 (e.g., the gate 1222 and the S/D contacts 1224) may be electrically coupled with the interconnect structures 1228 of the interconnect layers 1206-1210. The one or more interconnect layers 1206-1210 may form a metallization stack (also referred to as an “ILD stack”) 1219 of the integrated circuit device 1200.

The interconnect structures 1228 may be arranged within the interconnect layers 1206-1210 to route electrical signals according to a wide variety of designs; in particular, the arrangement is not limited to the particular configuration of interconnect structures 1228 depicted in FIG. 12. Although a particular number of interconnect layers 1206-1210 is depicted in FIG. 12, embodiments of the present disclosure include integrated circuit devices having more or fewer interconnect layers than depicted.

In some embodiments, the interconnect structures 1228 may include lines 1228a and/or vias 1228b filled with an electrically conductive material such as a metal. The lines 1228a may be arranged to route electrical signals in a direction of a plane that is substantially parallel with a surface of the die substrate 1202 upon which the device layer 1204 is formed. For example, the lines 1228a may route electrical signals in a direction in and out of the page and/or in a direction across the page from the perspective of FIG. 12. The vias 1228b may be arranged to route electrical signals in a direction of a plane that is substantially perpendicular to the surface of the die substrate 1202 upon which the device layer 1204 is formed. In some embodiments, the vias 1228b may electrically couple lines 1228a of different interconnect layers 1206-1210 together.

The interconnect layers 1206-1210 may include a dielectric material 1226 disposed between the interconnect structures 1228, as shown in FIG. 12. In some embodiments, dielectric material 1226 disposed between the interconnect structures 1228 in different ones of the interconnect layers 1206-1210 may have different compositions; in other embodiments, the composition of the dielectric material 1226 between different interconnect layers 1206-1210 may be the same. The device layer 1204 may include a dielectric material 1226 disposed between the transistors 1240 and a bottom layer of the metallization stack as well. The dielectric material 1226 included in the device layer 1204 may have a different composition than the dielectric material 1226 included in the interconnect layers 1206-1210; in other embodiments, the composition of the dielectric material 1226 in the device layer 1204 may be the same as a dielectric material 1226 included in any one of the interconnect layers 1206-1210.

A first interconnect layer 1206 (referred to as Metal 1 or “M1”) may be formed directly on the device layer 1204. In some embodiments, the first interconnect layer 1206 may include lines 1228a and/or vias 1228b, as shown. The lines 1228a of the first interconnect layer 1206 may be coupled with contacts (e.g., the S/D contacts 1224) of the device layer 1204. The vias 1228b of the first interconnect layer 1206 may be coupled with the lines 1228a of a second interconnect layer 1208.

The second interconnect layer 1208 (referred to as Metal 2 or “M2”) may be formed directly on the first interconnect layer 1206. In some embodiments, the second interconnect layer 1208 may include via 1228b to couple the lines 1228 of the second interconnect layer 1208 with the lines 1228a of a third interconnect layer 1210. Although the lines 1228a and the vias 1228b are structurally delineated with a line within individual interconnect layers for the sake of clarity, the lines 1228a and the vias 1228b may be structurally and/or materially contiguous (e.g., simultaneously filled during a dual-damascene process) in some embodiments.

The third interconnect layer 1210 (referred to as Metal 3 or “M3”) (and additional interconnect layers, as desired) may be formed in succession on the second interconnect layer 1208 according to similar techniques and configurations described in connection with the second interconnect layer 1208 or the first interconnect layer 1206. In some embodiments, the interconnect layers that are “higher up” in the metallization stack 1219 in the integrated circuit device 1200 (i.e., farther away from the device layer 1204) may be thicker that the interconnect layers that are lower in the metallization stack 1219, with lines 1228a and vias 1228b in the higher interconnect layers being thicker than those in the lower interconnect layers.

The integrated circuit device 1200 may include a solder resist material 1234 (e.g., polyimide or similar material) and one or more conductive contacts 1236 formed on the interconnect layers 1206-1210. In FIG. 12, the conductive contacts 1236 are illustrated as taking the form of bond pads. The conductive contacts 1236 may be electrically coupled with the interconnect structures 1228 and configured to route the electrical signals of the transistor(s) 1240 to external devices. For example, solder bonds may be formed on the one or more conductive contacts 1236 to mechanically and/or electrically couple an integrated circuit die including the integrated circuit device 1200 with another component (e.g., a printed circuit board). The integrated circuit device 1200 may include additional or alternate structures to route the electrical signals from the interconnect layers 1206-1210; for example, the conductive contacts 1236 may include other analogous features (e.g., posts) that route the electrical signals to external components.

In some embodiments in which the integrated circuit device 1200 is a double-sided die, the integrated circuit device 1200 may include another metallization stack (not shown) on the opposite side of the device layer(s) 1204. This metallization stack may include multiple interconnect layers as discussed above with reference to the interconnect layers 1206-1210, to provide conductive pathways (e.g., including conductive lines and vias) between the device layer(s) 1204 and additional conductive contacts (not shown) on the opposite side of the integrated circuit device 1200 from the conductive contacts 1236.

In other embodiments in which the integrated circuit device 1200 is a double-sided die, the integrated circuit device 1200 may include one or more through silicon vias (TSVs) through the die substrate 1202; these TSVs may make contact with the device layer(s) 1204, and may provide conductive pathways between the device layer(s) 1204 and additional conductive contacts (not shown) on the opposite side of the integrated circuit device 1200 from the conductive contacts 1236. In some embodiments, TSVs extending through the substrate can be used for routing power and ground signals from conductive contacts on the opposite side of the integrated circuit device 1200 from the conductive contacts 1236 to the transistors 1240 and any other components integrated into the die 1200, and the metallization stack 1219 can be used to route I/O signals from the conductive contacts 1236 to transistors 1240 and any other components integrated into the die 1200.

Multiple integrated circuit devices 1200 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

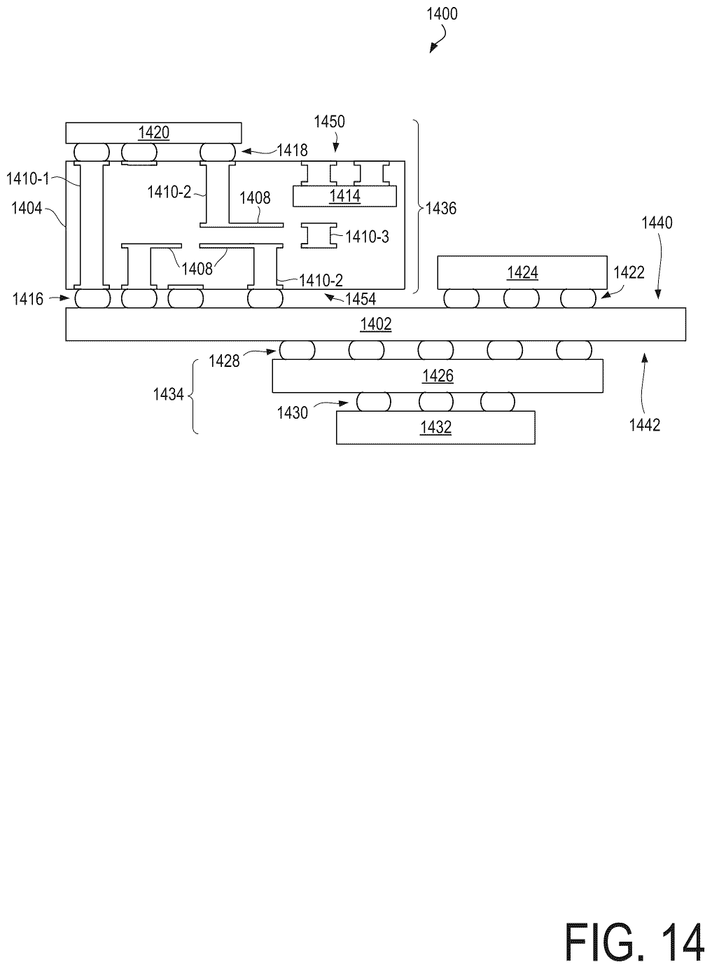

FIG. 14 is a cross-sectional side view of an integrated circuit device assembly 1400 that may include any of the microelectronic assemblies disclosed herein. The integrated circuit device assembly 1400 includes a number of components disposed on a circuit board 1402 (which may be a motherboard, system board, mainboard, etc.). The integrated circuit device assembly 1400 includes components disposed on a first face 1440 of the circuit board 1402 and an opposing second face 1442 of the circuit board 1402; generally, components may be disposed on one or both faces 1440 and 1442. Any of the integrated circuit components discussed below with reference to the integrated circuit device assembly 1400 may take the form of any suitable ones of the embodiments of the microelectronic assemblies disclosed herein.

In some embodiments, the circuit board 1402 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1402. In other embodiments, the circuit board 1402 may be a non-PCB substrate. The integrated circuit device assembly 1400 illustrated in FIG. 14 includes a package-on-interposer structure 1436 coupled to the first face 1440 of the circuit board 1402 by coupling components 1416. The coupling components 1416 may electrically and mechanically couple the package-on-interposer structure 1436 to the circuit board 1402, and may include solder balls (as shown in FIG. 14), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 1436 may include an integrated circuit component 1420 coupled to an interposer 1404 by coupling components 1418. The coupling components 1418 may take any suitable form for the application, such as the forms discussed above with reference to the coupling components 1416. Although a single integrated circuit component 1420 is shown in FIG. 14, multiple integrated circuit components may be coupled to the interposer 1404; indeed, additional interposers may be coupled to the interposer 1404. The interposer 1404 may provide an intervening substrate used to bridge the circuit board 1402 and the integrated circuit component 1420.

The integrated circuit component 1420 may be a packaged or unpacked integrated circuit product that includes one or more integrated circuit dies (e.g., the die 1102 of FIG. 11, the integrated circuit device 1200 of FIG. 12) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1420, a single monolithic integrated circuit die comprises solder bumps attached to contacts on the die. The solder bumps allow the die to be directly attached to the interposer 1404. The integrated circuit component 1420 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1420 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1420 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1420 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1404 may spread connections to a wider pitch or reroute a connection to a different connection. For example, the interposer 1404 may couple the integrated circuit component 1420 to a set of ball grid array (BGA) conductive contacts of the coupling components 1416 for coupling to the circuit board 1402. In the embodiment illustrated in FIG. 14, the integrated circuit component 1420 and the circuit board 1402 are attached to opposing sides of the interposer 1404; in other embodiments, the integrated circuit component 1420 and the circuit board 1402 may be attached to a same side of the interposer 1404. In some embodiments, three or more components may be interconnected by way of the interposer 1404.

In some embodiments, the interposer 1404 may be formed as a PCB, including multiple metal layers separated from one another by layers of dielectric material and interconnected by electrically conductive vias. In some embodiments, the interposer 1404 may be formed of an epoxy resin, a fiberglass-reinforced epoxy resin, an epoxy resin with inorganic fillers, a ceramic material, or a polymer material such as polyimide. In some embodiments, the interposer 1404 may be formed of alternate rigid or flexible materials that may include the same materials described above for use in a semiconductor substrate, such as silicon, germanium, and other group III-V and group IV materials. The interposer 1404 may include metal interconnects 1408 and vias 1410, including but not limited to through hole vias 1410-1 (that extend from a first face 1450 of the interposer 1404 to a second face 1454 of the interposer 1404), blind vias 1410-2 (that extend from the first or second faces 1450 or 1454 of the interposer 1404 to an internal metal layer), and buried vias 1410-3 (that connect internal metal layers).

In some embodiments, the interposer 1404 can comprise a silicon interposer. Through silicon vias (TSV) extending through the silicon interposer can connect connections on a first face of a silicon interposer to an opposing second face of the silicon interposer. In some embodiments, an interposer 1404 comprising a silicon interposer can further comprise one or more routing layers to route connections on a first face of the interposer 1404 to an opposing second face of the interposer 1404.

The interposer 1404 may further include embedded devices 1414, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1404. The package-on-interposer structure 1436 may take the form of any of the package-on-interposer structures known in the art. In embodiments where the interposer is a non-printed circuit board

The integrated circuit device assembly 1400 may include an integrated circuit component 1424 coupled to the first face 1440 of the circuit board 1402 by coupling components 1422. The coupling components 1422 may take the form of any of the embodiments discussed above with reference to the coupling components 1416, and the integrated circuit component 1424 may take the form of any of the embodiments discussed above with reference to the integrated circuit component 1420.

The integrated circuit device assembly 1400 illustrated in FIG. 14 includes a package-on-package structure 1434 coupled to the second face 1442 of the circuit board 1402 by coupling components 1428. The package-on-package structure 1434 may include an integrated circuit component 1426 and an integrated circuit component 1432 coupled together by coupling components 1430 such that the integrated circuit component 1426 is disposed between the circuit board 1402 and the integrated circuit component 1432. The coupling components 1428 and 1430 may take the form of any of the embodiments of the coupling components 1416 discussed above, and the integrated circuit components 1426 and 1432 may take the form of any of the embodiments of the integrated circuit component 1420 discussed above. The package-on-package structure 1434 may be configured in accordance with any of the package-on-package structures known in the art.

FIG. 15 is a block diagram of an example electrical device 1500 that may include one or more of the valleytronic devices disclosed herein. For example, any suitable ones of the components of the electrical device 1500 may include one or more of the integrated circuit device assemblies 1400, integrated circuit components 1420, integrated circuit devices 1200, or integrated circuit dies 1102 disclosed herein. A number of components are illustrated in FIG. 15 as included in the electrical device 1500, but any one or more of these components may be omitted or duplicated, as suitable for the application. In some embodiments, some or all of the components included in the electrical device 1500 may be attached to one or more motherboards mainboards, or system boards. In some embodiments, one or more of these components are fabricated onto a single system-on-a-chip (SoC) die.

Additionally, in various embodiments, the electrical device 1500 may not include one or more of the components illustrated in FIG. 15, but the electrical device 1500 may include interface circuitry for coupling to the one or more components. For example, the electrical device 1500 may not include a display device 1506, but may include display device interface circuitry (e.g., a connector and driver circuitry) to which a display device 1506 may be coupled. In another set of examples, the electrical device 1500 may not include an audio input device 1524 or an audio output device 1508, but may include audio input or output device interface circuitry (e.g., connectors and supporting circuitry) to which an audio input device 1524 or audio output device 1508 may be coupled.

The electrical device 1500 may include one or more processor units 1502 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1502 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1500 may include a memory 1504, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1504 may include memory that is located on the same integrated circuit die as the processor unit 1502. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1500 can comprise one or more processor units 1502 that are heterogeneous or asymmetric to another processor unit 1502 in the electrical device 1500. There can be a variety of differences between the processing units 1502 in a system in terms of a spectrum of metrics of merit including architectural, microarchitectural, thermal, power consumption characteristics, and the like. These differences can effectively manifest themselves as asymmetry and heterogeneity among the processor units 1502 in the electrical device 1500.

In some embodiments, the electrical device 1500 may include a communication component 1512 (e.g., one or more communication components). For example, the communication component 1512 can manage wireless communications for the transfer of data to and from the electrical device 1500. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1512 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1512 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1512 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1512 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1512 may operate in accordance with other wireless protocols in other embodiments. The electrical device 1500 may include an antenna 1522 to facilitate wireless communications and/or to receive other wireless communications (such as AM or FM radio transmissions).

In some embodiments, the communication component 1512 may manage wired communications, such as electrical, optical, or any other suitable communication protocols (e.g., IEEE 802.3 Ethernet standards). As noted above, the communication component 1512 may include multiple communication components. For instance, a first communication component 1512 may be dedicated to shorter-range wireless communications such as Wi-Fi or Bluetooth, and a second communication component 1512 may be dedicated to longer-range wireless communications such as global positioning system (GPS), EDGE, GPRS, CDMA, WiMAX, LTE, EV-DO, or others. In some embodiments, a first communication component 1512 may be dedicated to wireless communications, and a second communication component 1512 may be dedicated to wired communications.

The electrical device 1500 may include battery/power circuitry 1514. The battery/power circuitry 1514 may include one or more energy storage devices (e.g., batteries or capacitors) and/or circuitry for coupling components of the electrical device 1500 to an energy source separate from the electrical device 1500 (e.g., AC line power).

The electrical device 1500 may include a display device 1506 (or corresponding interface circuitry, as discussed above). The display device 1506 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1500 may include an audio output device 1508 (or corresponding interface circuitry, as discussed above). The audio output device 1508 may include any embedded or wired or wirelessly connected external device that generates an audible indicator, such speakers, headsets, or earbuds.

The electrical device 1500 may include an audio input device 1524 (or corresponding interface circuitry, as discussed above). The audio input device 1524 may include any embedded or wired or wirelessly connected device that generates a signal representative of a sound, such as microphones, microphone arrays, or digital instruments (e.g., instruments having a musical instrument digital interface (MIDI) output). The electrical device 1500 may include a Global Navigation Satellite System (GNSS) device 1518 (or corresponding interface circuitry, as discussed above), such as a Global Positioning System (GPS) device. The GNSS device 1518 may be in communication with a satellite-based system and may determine a geolocation of the electrical device 1500 based on information received from one or more GNSS satellites, as known in the art.

The electrical device 1500 may include an other output device 1510 (or corresponding interface circuitry, as discussed above). Examples of the other output device 1510 may include an audio codec, a video codec, a printer, a wired or wireless transmitter for providing information to other devices, or an additional storage device.

The electrical device 1500 may include an other input device 1520 (or corresponding interface circuitry, as discussed above). Examples of the other input device 1520 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1500 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1500 may be any other electronic device that processes data. In some embodiments, the electrical device 1500 may comprise multiple discrete physical components. Given the range of devices that the electrical device 1500 can be manifested as in various embodiments, in some embodiments, the electrical device 1500 can be referred to as a computing device or a computing system.

As used in this application and the claims, a list of items joined by the term “and/or” can mean any combination of the listed items. For example, the phrase “A, B and/or C” can mean A; B; C; A and B; A and C; B and C; or A, B and C. As used in this application and the claims, a list of items joined by the term “at least one of” can mean any combination of the listed terms. For example, the phrase “at least one of A, B or C” can mean A; B; C; A and B; A and C; B and C; or A, B, and C. Moreover, as used in this application and the claims, a list of items joined by the term “one or more of” can mean any combination of the listed terms. For example, the phrase “one or more of A, B and C” can mean A; B; C; A and B; A and C; B and C; or A, B, and C.

As used in this application and the claims, the phrase “individual of” or “respective of” following by a list of items recited or stated as having a trait, feature, etc. means that all of the items in the list possess the stated or recited trait, feature, etc. For example, the phrase “individual of A, B, or C, comprise a sidewall” or “respective of A, B, or C, comprise a sidewall” means that A comprises a sidewall, B comprises sidewall, and C comprises a sidewall.

The disclosed methods, apparatuses, and systems are not to be construed as limiting in any way. Instead, the present disclosure is directed toward all novel and nonobvious features and aspects of the various disclosed embodiments, alone and in various combinations and subcombinations with one another. The disclosed methods, apparatuses, and systems are not limited to any specific aspect or feature or combination thereof, nor do the disclosed embodiments require that any one or more specific advantages be present or problems be solved.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods.

The following examples pertain to additional embodiments of technologies disclosed herein.

Example 1 is an apparatus comprising: a first layer comprising a first portion extending along a first axis and a second portion extending along a second axis, the first axis substantially orthogonal to the second axis, the first layer comprising: tin and sulfur; tin and selenium; tin and tellurium; germanium and sulfur; germanium and tellurium; or germanium and selenium; a ferromagnet; a second layer located on a surface of the first layer at a first end portion of the first portion of the first layer, the second layer positioned between the ferromagnet and the first layer; and a dielectric layer positioned adjacent to the surface of the first layer at a third portion of the first layer, the third portion of the first layer positioned between the first end portion of the first portion of the first layer and a second end portion of the first portion of the first layer.

Example 2 comprises the apparatus of claim 1, further comprising: a first conductive trace positioned adjacent to the ferromagnet; a second conductive trace positioned adjacent to the dielectric layer; a third conductive trace positioned adjacent to the surface of the first layer at the second end portion of the first portion of the first layer, the second end portion of the first layer opposite the first end portion of the first layer; a fourth conductive trace positioned adjacent to the surface of the first layer at a first end portion of the second portion of the first layer; and a fifth conductive trace positioned adjacent to the surface of the first layer at a second end portion of the second portion of the first layer, the second end portion of the first layer positioned opposite the first end portion of the first layer.

Example 3 is an apparatus comprising: a first layer comprising a first portion extending along a first axis and a second portion extending along a second axis, the first axis substantially orthogonal to the second axis, the first layer comprising: tin and sulfur; tin and selenium; tin and tellurium; germanium and sulfur; germanium and tellurium; or germanium and selenium; a ferromagnet; a second layer located on a first surface of the first layer at a first end portion of the first portion of the first layer, the second layer positioned between the ferromagnet and the first layer; and a dielectric layer positioned adjacent to a second surface of the first layer that is opposite the first surface of the first layer.

Example 4 comprises the apparatus of claim 3, further comprising: a first conductive trace positioned adjacent to the ferromagnet; a second conductive trace positioned adjacent to the dielectric layer; a third conductive trace positioned adjacent to the first surface of the first layer at a second end portion of the first portion of the first layer; a fourth conductive trace positioned adjacent to the first surface of the first layer at a first end portion of the second portion of the first layer; and a fifth conductive trace positioned adjacent to the first surface of the first layer at a second end portion of the second portion of the first layer, the second end portion of the second portion of the first layer opposite the first end portion of the second portion of the first layer.

Example 5 is an apparatus comprising: a first layer comprising a longitudinal portion extending along a first axis and a transverse portion extending along a second axis, the first axis substantially orthogonal to the second axis, the first layer comprising; tin and sulfur; tin and selenium; tin and tellurium; germanium and sulfur; germanium and tellurium; or germanium and selenium; a ferromagnet; a second layer located on a surface of the first layer at a first portion of the longitudinal portion of the first layer, the second layer positioned between the ferromagnet and the first layer; and a dielectric layer positioned adjacent to the surface of the first layer at a third portion of the first layer, the third portion of the first layer positioned between the first portion of the longitudinal portion of the first layer and a second portion of the longitudinal portion of the first layer.

Example 6 comprises the apparatus of claim 5, further comprising: a first conductive trace positioned adjacent to the ferromagnet; a second conductive trace positioned adjacent to the dielectric layer; a third conductive trace positioned adjacent to the surface of the first layer at the second portion of the longitudinal portion of the first layer; a fourth conductive trace positioned adjacent to the surface of the first layer at a first portion of the transverse portion of the first layer; and a fifth conductive trace positioned adjacent to the surface of the first layer at a second.

Example 7 comprises an apparatus comprising: a first layer comprising a longitudinal portion extending along a first axis and a transverse portion extending along a second axis, the first axis substantially orthogonal to the second axis, the first layer comprising: tin and sulfur; tin and selenium; tin and tellurium; germanium and sulfur; germanium and tellurium; or germanium and selenium; a ferromagnet; a second layer located on a first surface of the first layer at a first portion of the longitudinal portion of the first layer, the second layer positioned between the ferromagnet and the first layer; and a dielectric layer positioned adjacent to a second surface of the first layer, the second surface of the first layer opposite the first surface of the first layer.

Example 8 comprises the apparatus of claim 7, further comprising: a first conductive trace positioned adjacent to the ferromagnet; a second conductive trace positioned adjacent to the dielectric layer; a third conductive trace positioned adjacent to the first surface of the longitudinal portion at a second portion of the longitudinal portion of the first layer, the second portion of the longitudinal portion located opposite the first portion of the longitudinal portion relative to a third portion of the first layer, the third portion of the first layer common to the longitudinal portion of the first layer and the transverse portion of the first layer; a fourth conductive trace positioned adjacent to the first surface of the first layer at a first portion of the transverse portion of the first layer; and a fifth conductive trace positioned adjacent to the first surface of the first layer at a second portion of the transverse portion of the first layer, the second portion of the transverse portion of the first layer opposite the first portion of the transverse portion of the first layer relative to the third portion of the first layer.

Example 9 comprises the apparatus of any one of examples 1-4, wherein the third portion of the first layer is common to the first portion of the first layer and the second portion of the first layer.

Example 10 comprises the apparatus of any one of examples 5-8, wherein the third portion of the first layer is common to the longitudinal portion of the first layer and the transverse portion of the first layer.

Example 11 comprises the apparatus of example 7 or 8, wherein the dielectric layer is positioned adjacent to the second surface of the first layer at the third portion of the first layer.

Example 12 comprises the apparatus of any one of examples 1, 2, 5, or 6, wherein the second layer is positioned adjacent to the surface of the first layer.

Example 13 comprises the apparatus of any one of examples 3, 4, 7, or 8, wherein the second layer is positioned adjacent to the first surface of the first layer.

Example 14 comprises the apparatus of any one of examples 1-13, wherein the second layer comprises: magnesium and oxygen; aluminum and oxygen; or titanium and oxygen.

Example 15 comprises the apparatus of any one of examples 1-13, wherein the second layer comprises: lanthanum, aluminum, and oxygen; tungsten and oxygen; sodium, tantalum, and oxygen; strontium, titanium, and oxygen; barium, titanium, and oxygen; potassium, tantalum, and oxygen; or lithium, niobium, and oxygen.

Example 16 comprises the apparatus of any one of examples 1-15, wherein a thickness of the second layer is in a range of 0.5-10 nanometers.

Example 17 comprises the apparatus of any one of examples 1-15, wherein a thickness of the second layer is in a range of 0.5-2.0 nanometers.

Example 18 comprises the apparatus of any one of examples 1-17, wherein the first layer comprises tin and sulfur.

Example 19 comprises the apparatus of any one of examples 1-17, wherein the first layer comprises tin and selenium.

Example 20 comprises the apparatus of any one of examples 1-17, wherein the first layer comprises tin and tellurium.

Example 21 comprises the apparatus of any one of examples 1-17, wherein the first layer comprises germanium and sulfur.

Example 22 comprises the apparatus of any one of examples 1-17, wherein the first layer comprises germanium and tellurium.

Example 23 comprises the apparatus of any one of examples 1-17, wherein the first layer comprises germanium and selenium.

Example 24 comprises the apparatus of any one of examples 1-17, wherein the first layer comprises tin and two of sulfur, selenium, and tellurium.

Example 25 comprises the apparatus of any one of examples 1-17, wherein the first layer comprises germanium and two of sulfur, selenium, and tellurium.

Example 26 comprises the apparatus of any one of examples 1-17, wherein the first layer comprises tin, germanium, and one of sulfur, selenium, and tellurium.

Example 27 comprises the apparatus of any one of examples 1-26, wherein the ferromagnet comprises cobalt, iron, nickel, or gadolinium.

Example 28 comprises the apparatus of any one of examples 1-26, wherein the ferromagnet comprises lanthanum, strontium, manganese, and oxygen.

Example 29 comprises the apparatus of any one of examples 1-28, wherein the first conductive trace, the second conductive trace, the third conductive trace, the fourth conductive trace, and/or the fifth conductive trace comprise copper, silver, aluminum, gold, cobalt, tungsten, tantalum, or nickel.

Example 30 comprises the apparatus of any one of examples 1-29, wherein a thickness of the first layer is in a range of 1-15 nanometers.

Example 31 comprises the apparatus of any one of examples 1-30, wherein the first layer is a monolayer.

Example 32 comprises the apparatus of any one of examples 1-31, further comprising a third layer positioned between the second layer and the first layer, the third layer comprising copper.

Example 33 comprises the apparatus of any one of examples 1-31, further comprising a third layer positioned between the second layer and the first layer, the third layer comprising: strontium, titanium, and oxygen; strontium, ruthenium, and oxygen; or calcium, manganese, and oxygen.

Example 34 comprises the apparatus of any one of examples 1-33, wherein the apparatus is a processor unit.

Example 35 comprises the apparatus of any one of examples 1-34, wherein the apparatus is an integrated circuit component.

Example 36 comprises the apparatus of example 34 or 35, wherein the apparatus further comprises one or more electronic transistors.

Example 37 comprises the apparatus of any one of examples 1-36 wherein the apparatus comprises a printed circuit board and an integrated circuit component attached to the printed circuit board, the integrated circuit component comprising the first layer, the second layer, the ferromagnet, and the dielectric layer.

Example 38 comprises the apparatus of example 37 wherein the apparatus further comprises one or more memories attached to the printed circuit board.

Example 39 comprises the apparatus of example 37, further comprising a housing enclosing the printed circuit board and the integrated circuit component.

Example 40 is a method, comprising: forming a first layer comprising a first portion extending along a first axis and a second portion extending along a second axis, the first axis substantially orthogonal to the second axis, the first layer comprising: tin and sulfur; tin and selenium; tin and tellurium; germanium and sulfur; germanium and tellurium; or germanium and selenium; forming a second layer located on a surface of the first layer at a first end portion of the first portion of the first layer; forming a ferromagnet positioned adjacent to the second layer; forming a dielectric layer positioned adjacent to the surface of the first layer at a third portion of the first layer, the third portion of the first layer positioned between the first end portion of the first portion of the first layer and a second end portion of the first portion of the first layer; forming a first conductive trace positioned adjacent to the ferromagnet; forming a second conductive trace positioned adjacent to the dielectric layer; forming a third conductive trace positioned adjacent to the surface of the first layer at the second end portion of the first portion of the first layer, the second end portion of the first layer opposite the first end portion of the first layer; forming a fourth conductive trace positioned adjacent to the surface of the first layer at a first end portion of the second portion of the first layer; and forming a fifth conductive trace positioned adjacent to the surface of the first layer at a second end portion of the second portion of the first layer, the second end portion of the second portion of the first layer opposite the first end portion of the second portion of the first layer.

Example 41 is a method comprising: forming a first conductive trace; forming a dielectric layer positioned adjacent to the first conductive trace; forming a first layer comprising a first portion extending along a first axis and a second portion extending along a second axis, the first axis substantially orthogonal to the second axis, the first layer comprising a first surface and a second surface opposite the first surface, the dielectric layer positioned adjacent to the second surface of the first layer, the first layer comprising: tin and sulfur; tin and selenium; tin and tellurium; germanium and sulfur; germanium and tellurium; or germanium and selenium; forming a second layer located on the first surface of the first layer at a first end portion of the first portion of the first layer; forming a ferromagnet positioned adjacent to the second layer; forming a second conductive trace positioned adjacent to the ferromagnet; forming a third conductive trace positioned adjacent to the first surface of the first layer at a second end portion of the first portion of the first layer, the second end portion of the first portion of the first layer opposite the first end portion of the first portion of the first layer; forming a fourth conductive trace positioned adjacent to the first surface of the first layer at a first end portion of the second portion of the first layer; and forming a fifth conductive trace positioned adjacent to the first surface of the first layer at a second end portion of the second portion of the first layer, the second end portion of the second portion of the first layer opposite the first end portion of the second portion of the first layer.

Example 42 comprises the method of example 40 or 41, wherein the third portion of the first layer is common to the first portion of the first layer and the second portion of the first layer.

Example 43 comprises the method of example 40, wherein the second layer is positioned adjacent to the surface of the first layer.

Example 44 comprises the method of example 41, wherein the second layer is positioned adjacent to the first surface of the first layer.

Example 45 comprises the method of any one of examples 40-44, wherein the second layer comprises: magnesium and oxygen; aluminum and oxygen; or titanium and oxygen.

Example 46 comprises the method of any one of examples 40-44, wherein the second layer comprises: lanthanum, aluminum, and oxygen; tungsten and oxygen; sodium, tantalum, and oxygen; strontium, titanium, and oxygen; barium, titanium, and oxygen; potassium, tantalum, and oxygen; or lithium, niobium, and oxygen.

Example 47 comprises the method of any one of examples 40-46, wherein a thickness of the second layer is in a range of 0.5-10 nanometers.

Example 48 comprises the method of any one of examples 40-46, wherein a thickness of the second layer is in a range of 0.5-2.0 nanometers.

Example 49 comprises the method of any one of examples 40-48, wherein the first layer comprises tin and sulfur.

Example 50 comprises the method of any one of examples 40-48, wherein the first layer comprises tin and selenium.

Example 51 comprises the method of any one of examples 40-48, wherein the first layer comprises tin and tellurium.

Example 52 comprises the method of any one of examples 40-48, wherein the first layer comprises germanium and sulfur.

Example 53 comprises the method of any one of examples 40-48, wherein the first layer comprises germanium and tellurium.

Example 54 comprises the method of any one of examples 40-48, wherein the first layer comprises germanium and selenium.

Example 55 comprises the method of any one of examples 40-48, wherein the first layer comprises tin and two of sulfur, selenium, and tellurium.

Example 56 comprises the method of any one of examples 40-48, wherein the first layer comprises germanium and two of sulfur, selenium, and tellurium.

Example 57 comprises the method of any one of examples 40-48, wherein the first layer comprises tin, germanium, and one of sulfur, selenium, and tellurium.

Example 58 comprises the method of any one of examples 40-57, wherein the ferromagnet comprises cobalt, iron, nickel, or gadolinium.

Example 59 comprises the method of any one of examples 40-58, wherein the ferromagnet comprises lanthanum, strontium, manganese, and oxygen.

Example 60 comprises the method of any one of examples 40-59, wherein the first conductive trace, the second conductive trace, the third conductive trace, the fourth conductive trace, and/or the fifth conductive trace comprise copper, silver, aluminum, gold, cobalt, tungsten, tantalum, or nickel.

Example 61 comprises the method of any one of examples 40-60, wherein a thickness of the first layer is in a range of 1-15 nm.

Example 62 comprises the method of any one of examples 40-61, wherein the first layer is a monolayer.

Example 63 comprises the method of any one of examples 40-62, further comprising a third layer positioned between the second layer and the first layer, the third layer comprising copper.

Example 64 comprises the method of any one of examples 40-62, further comprising a third layer positioned between the second layer and the first layer, the third layer comprising: strontium, titanium, and oxygen; strontium, ruthenium, and oxygen; or calcium, manganese, and oxygen.

Example 65 comprises the method of example 40, wherein forming the first layer comprises forming the first layer on an integrated circuit structure.

Example 66 comprises the method of example 41, wherein forming the first conductive trace comprises forming the first conductive trace on an integrated circuit structure.

Example 67 comprises the method of example 65 or 66, wherein the integrated circuit structure comprises a die substrate.

1. An apparatus comprising:
a first layer comprising a first portion extending along a first axis and a second portion extending along a second axis, the first axis substantially orthogonal to the second axis, the first layer comprising:
tin and sulfur;
tin and selenium;
tin and tellurium;
germanium and sulfur;
germanium and tellurium; or
germanium and selenium;
a ferromagnet;
a second layer located on a surface of the first layer at a first end portion of the first portion of the first layer, the second layer positioned between the ferromagnet and the first layer; and
a dielectric layer positioned adjacent to the surface of the first layer at a third portion of the first layer, the third portion of the first layer positioned between the first end portion of the first portion of the first layer and a second end portion of the first portion of the first layer.

2. The apparatus of claim 1, further comprising:
a first conductive trace positioned adjacent to the ferromagnet;
a second conductive trace positioned adjacent to the dielectric layer;
a third conductive trace positioned adjacent to the surface of the first layer at the second end portion of the first portion of the first layer, the second end portion of the first layer opposite the first end portion of the first layer;
a fourth conductive trace positioned adjacent to the surface of the first layer at a first end portion of the second portion of the first layer; and
a fifth conductive trace positioned adjacent to the surface of the first layer at a second end portion of the second portion of the first layer, the second end portion of the first layer positioned opposite the first end portion of the first layer.

3. The apparatus of claim 2, wherein the first conductive trace, the second conductive trace, the third conductive trace, the fourth conductive trace, and/or the fifth conductive trace comprise copper, silver, aluminum, gold, cobalt, tungsten, tantalum, or nickel.

4. The apparatus of claim 1, wherein the third portion of the first layer is common to the first portion of the first layer and the second portion of the first layer.

5. The apparatus of claim 1 wherein the second layer is positioned adjacent to the surface of the first layer.

6. The apparatus of claim 1, wherein the second layer comprises:
magnesium and oxygen;
aluminum and oxygen;
titanium and oxygen;
lanthanum, aluminum, and oxygen;
tungsten and oxygen;
sodium, tantalum, and oxygen;
strontium, titanium, and oxygen;
barium, titanium, and oxygen;
potassium, tantalum, and oxygen; or
lithium, niobium, and oxygen.

7. The apparatus of claim 1, wherein the ferromagnet comprises cobalt, iron, nickel, or gadolinium.

8. The apparatus of claim 1, wherein a thickness of the first layer is in a range of 1-15 nanometers.

9. The apparatus of claim 1, further comprising a third layer positioned between the second layer and the first layer, the third layer comprising copper.

10. The apparatus of claim 1, wherein the apparatus is an integrated circuit component.

11. The apparatus of claim 1, wherein the apparatus comprises a printed circuit board and an integrated circuit component attached to the printed circuit board, the integrated circuit component comprising the first layer, the second layer, the ferromagnet, and the dielectric layer.

12. The apparatus of claim 11, wherein the apparatus further comprises one or more memories attached to the printed circuit board.

13. An apparatus comprising:
a first layer comprising a first portion extending along a first axis and a second portion extending along a second axis, the first axis substantially orthogonal to the second axis, the first layer comprising:
tin and sulfur;
tin and selenium;
tin and tellurium;
germanium and sulfur;
germanium and tellurium; or
germanium and selenium;
a ferromagnet;
a second layer located on a first surface of the first layer at a first end portion of the first portion of the first layer, the second layer positioned between the ferromagnet and the first layer; and
a dielectric layer positioned adjacent to a second surface of the first layer that is opposite the first surface of the first layer.

14. The apparatus of claim 13, further comprising:
a first conductive trace positioned adjacent to the ferromagnet;
a second conductive trace positioned adjacent to the dielectric layer;
a third conductive trace positioned adjacent to the first surface of the first layer at a second end portion of the first portion of the first layer;
a fourth conductive trace positioned adjacent to the first surface of the first layer at a first end portion of the second portion of the first layer; and
a fifth conductive trace positioned adjacent to the first surface of the first layer at a second end portion of the second portion of the first layer, the second end portion of the second portion of the first layer opposite the first end portion of the second portion of the first layer.

15. The apparatus of claim 14, wherein the first conductive trace, the second conductive trace, the third conductive trace, the fourth conductive trace, and/or the fifth conductive trace comprise copper, silver, aluminum, gold, cobalt, tungsten, tantalum, or nickel.

16. The apparatus of claim 13, wherein the third portion of the first layer is common to the first portion of the first layer and the second portion of the first layer.

17. The apparatus of claim 13, wherein the second layer is positioned adjacent to the first surface of the first layer.

18. The apparatus of claim 13, wherein the second layer comprises:
magnesium and oxygen;
aluminum and oxygen;
titanium and oxygen;
lanthanum, aluminum, and oxygen;
tungsten and oxygen;
sodium, tantalum, and oxygen;
strontium, titanium, and oxygen;
barium, titanium, and oxygen;
potassium, tantalum, and oxygen; or
lithium, niobium, and oxygen.

19. The apparatus of claim 13, wherein a thickness of the second layer is in a range of 0.5-2.0 nanometers.

20. The apparatus of claim 13, wherein the ferromagnet comprises cobalt, iron, nickel, or gadolinium.

21. The apparatus of claim 13, wherein the ferromagnet comprises lanthanum, strontium, manganese, and oxygen.

22. The apparatus of claim 13, wherein a thickness of the first layer is in a range of 1-15 nanometers.

23. The apparatus of claim 13, further comprising a third layer positioned between the second layer and the first layer, the third layer comprising copper.

24. The apparatus of claim 13, wherein the apparatus is an integrated circuit component.

25. The apparatus of claim 13, wherein the apparatus comprises a printed circuit board and an integrated circuit component attached to the printed circuit board, the integrated circuit component comprising the first layer, the second layer, the ferromagnet, and the dielectric layer.
